(19) United States
(12) Patent Application Publication
(10) Pub. No.: US 2019/0181347 A1
(43) Pub. Date: Jun. 13, 2019

(54) ORGANIC ELECTRONIC MATERIAL AND ORGANIC ELECTRONIC ELEMENT

(71) Applicant: HITACHI CHEMICAL COMPANY, LTD., Tokyo (JP)

(72) Inventors: Kenichi ISHITSUKA, Nagareyama-shi, Chiba (JP); Shigeaki FUNYUU, Tsuchiura-shi, Ibaraki (JP); Naoki ASANO, Tsukuba-shi, Ibaraki (JP); Daisuke RYUZAKI, Tsuchiura-shi, Ibaraki (JP); Hiroshi TAKAIRA, Hitachinaka-shi, Ibaraki (JP); Yuki YOSHINARI, Tsukuba-shi, Ibaraki (JP)

(21) Appl. No.: 16/307,750

(22) PCT Filed: Jun. 8, 2016
(86) PCT No.: PCT/JP2016/066991

§ 371 Date: Dec. 6, 2018

(51) Int. Cl. H01L 51/00; G02F 1/1335

(52) U.S. Cl. CPC H01L 51/0035; H01L 51/5056; G02F 1/133603

(57) ABSTRACT

An embodiment of the present invention relates to an organic electronic material containing a charge transport polymer or oligomer having, at least at one terminal, a condensed polycyclic aromatic hydrocarbon moiety having three or more benzene rings.

### TECHNICAL FIELD

Embodiments of the present invention relate to an organic electronic material, an ink composition, an organic layer, an organic electronic element, an organic electroluminescent element (hereafter also referred to as an “organic EL element”), a display element, an illumination device and a display device.

### BACKGROUND ART

Organic EL elements are attracting attention for potential use in large-surface area solid state lighting source applications to replace incandescent lamps or gas-filled lamps or the like. Further, organic EL elements are also attracting attention as the leading self-luminous display for replacing liquid crystal displays (LCD) in the field of flat panel displays (FPD), and commercial products are becoming increasingly available.

Depending on the organic materials used, organic EL elements are broadly classified into low-molecular weight type organic EL elements and polymer type organic EL elements. In polymer type organic EL elements, a polymer compound is used as the organic material, whereas in low molecular weight type organic EL elements, a low-molecular weight compound is used. On the other hand, the production methods for organic EL elements are broadly classified into dry processes in which film formation is mainly performed in a vacuum system, and wet processes in which film formation is performed by plate-based printing such as relief printing or intaglio printing, or by plateless printing such as inkjet printing. Because wet processes enable simple film formation, they are expected to be an indispensable method in the production of future large-screen organic EL displays (for example, see Patent Literature 1 and Non Patent Literature 1).

### CITATION LIST

### Patent Literature

PLT 1: JP 2006-279007 A

### Non Patent Literature

NPL 1: Kengo Hirose, Daisuke Kumaki, Nobuaki Koike, Akira Kuriyama, Seiichiro Ikehata, and Shizuo Tokito, 53rd Meeting of the Japan Society of Applied Physics and Related Societies, 26p-ZK-4 (2006)

### SUMMARY OF INVENTION

### Technical Problem

Organic EL elements produced using wet processes have the advantages that cost reductions and surface area increases can be achieved with relative ease. However, in terms of the characteristics of organic EL elements, organic EL elements containing an organic layer produced using a wet process still require further improvement.

One embodiment of the present invention has been developed in light of the above circumstances, and has the object of providing an organic electronic material that is suited to wet processes, and is suitable for improving the lifespan characteristics of organic electronic elements. Further, other embodiments of the present invention have the objects of providing an ink composition and an organic layer that are suitable for improving the lifespan characteristics of organic electronic elements. Moreover, other embodiments of the present invention provide an organic electronic element, an organic EL element, a display element, an illumination device and a display device that exhibit excellent lifespan characteristics.

### Solution to Problem

As a result of intensive investigation, the inventors of the present invention discovered an organic electronic material that was suited to wet processes and suitable for improving the lifespan characteristics of organic electronic elements, and they were therefore able to complete the present invention.

In other words, one embodiment of the present invention relates to an organic electronic material containing a charge transport polymer or oligomer having, at least at one terminal, a condensed polycyclic aromatic hydrocarbon moiety having three or more benzene rings.

In one preferred embodiment, the above charge transport polymer or oligomer has three or more terminals. It is preferable that the charge transport polymer or oligomer has the condensed polycyclic aromatic hydrocarbon moiety described above at 25% or more of all the terminals.

In one preferred embodiment, the condensed polycyclic aromatic hydrocarbon moiety described above includes at least one type of moiety selected from the group consisting of an anthracene moiety, tetracene moiety, pentacene moiety, phenanthrene moiety, chrysene moiety, triphenylene moiety, tetraphene moiety, pyrene moiety, picene moiety, pentaphene moiety, perylene moiety, pentahelicene moiety, hexahelicene moiety, heptahelicene moiety and coronene moiety.

In one preferred embodiment, the condensed polycyclic aromatic hydrocarbon moiety includes a condensed polycyclic aromatic hydrocarbon moiety having 3 to 8 benzene rings.

Further, in one preferred embodiment, the charge transport polymer or oligomer also has a polymerizable substituent.

Another embodiment of the present invention relates to an ink composition containing one of the organic electronic materials described above and a solvent.

Further, another embodiment of the present invention relates to an organic layer formed using one of the organic electronic materials or the ink composition described above.

Further, other embodiments of the present invention relate to an organic electronic element and an organic electroluminescent element that have at least one of the above organic layer. In one preferred embodiment, the organic electroluminescent element also has a flexible substrate. In one preferred embodiment, the organic electroluminescent element also has a resin film substrate.

Moreover, other embodiments of the present invention relate to a display element and an illumination device provided with one of organic electroluminescent elements described above, and a display device provided with the illumination device and a liquid crystal element as a display unit.

The present application is related to the subject matter disclosed in prior Japanese Application 2014-251848 filed on Dec. 12, 2014, the entire contents of which are incorporated by reference herein.

### Advantageous Effects of Invention

The organic electronic material, ink composition and organic layer that represent embodiments of the present invention are able to provide an organic electronic element having excellent lifespan characteristics. Further, the organic electronic element, organic EL element, display element, illumination device and display device that represent other embodiments of the present invention exhibit excellent lifespan characteristics.

### BRIEF DESCRIPTION OF DRAWINGS

FIG. 1 is a cross-sectional schematic view illustrating one example of an organic EL element that represents one embodiment of the present invention.

### DESCRIPTION OF EMBODIMENTS

Embodiments of the present invention are described below, but the present invention is not limited to the following embodiments. The preferred embodiments may be used alone, or appropriate combinations of the embodiments may be used.

### <Organic Electronic Material>

The organic electronic material of one embodiment of the present invention contains a charge transport polymer or oligomer having, at least at one terminal, a condensed polycyclic aromatic hydrocarbon moiety having three or more benzene rings. The organic electronic material may contain only one type of the charge transport polymer or oligomer, or may contain two or more types. Charge transport polymers or oligomers are preferred in terms of offering superior film formability by wet processes compared with low-molecular weight compounds.

### [Charge Transport Polymer or Oligomer]

The charge transport polymer or oligomer has the ability to transport an electric charge. The transported charge is preferably a positive hole.

(Structural Unit having Charge Transport Properties)

The charge transport polymer or oligomer has a structural unit having charge transport properties. There are no particular limitations on the structural unit having charge transport properties, provided it includes an atom grouping having the ability to transport an electric charge.

The charge transport polymer or oligomer may have only one type of structural unit having charge transport properties, or may have two or more types. The structural unit having charge transport properties preferably includes, as an atom grouping, an amine structure having an aromatic ring (hereafter also referred to as an “aromatic amine”), a carbazole structure, a thiophene structure, a fluorene structure, a benzene structure or a pyrrole structure, wherein the structure has hole transport properties.

From the viewpoint of achieving superior hole transport properties, it is particularly preferable that the structural unit having charge transport properties includes, as an atom grouping, an amine structure having an aromatic ring (hereafter also referred to as an “aromatic amine”), a carbazole structure or a thiophene structure. A triarylamine is preferred as the aromatic amine, and triphenylamine is particularly desirable.

The charge transport polymer or oligomer may have, as the structural unit having charge transport properties, a single type of unit selected from among units having an aromatic amine structure, units having a carbazole structure, and units having a thiophene structure, or may have two or more types of these structural units. The charge transport polymer or oligomer preferably has a unit having an aromatic amine structure and/or a unit having a carbazole structure.

The charge transport polymer or oligomer preferably includes the structural unit having hole transport properties at least as a divalent structure.

Structural units (1a) to (84a) that represent specific examples of structural units having hole transport properties are shown below. The following examples are examples of divalent structural units.

<Structural Units (1a) to (84a)>

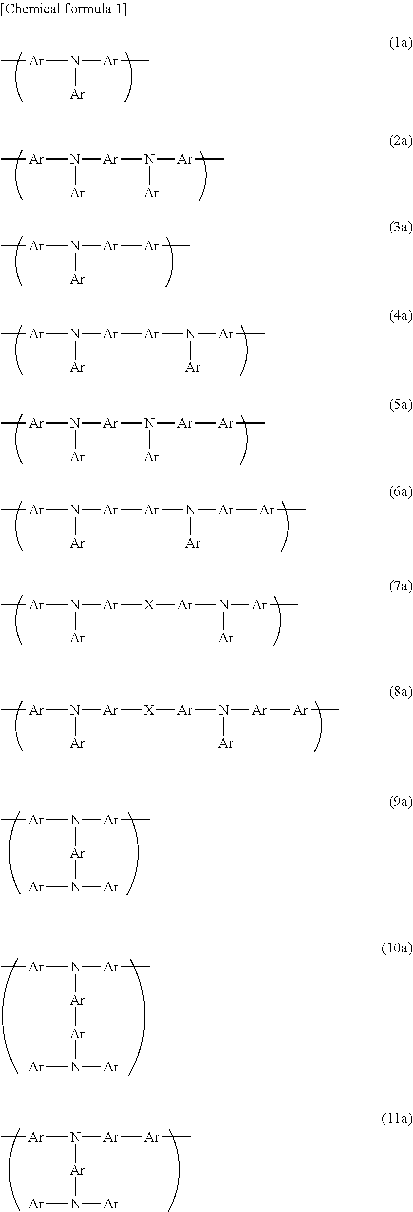

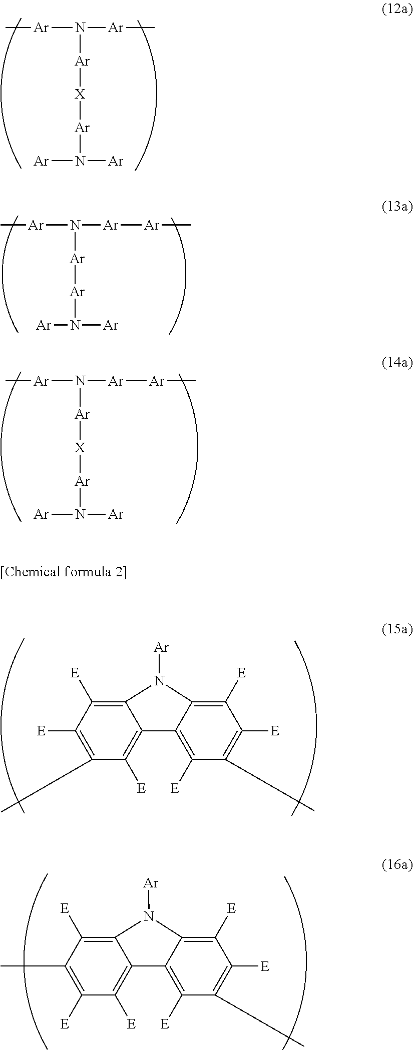

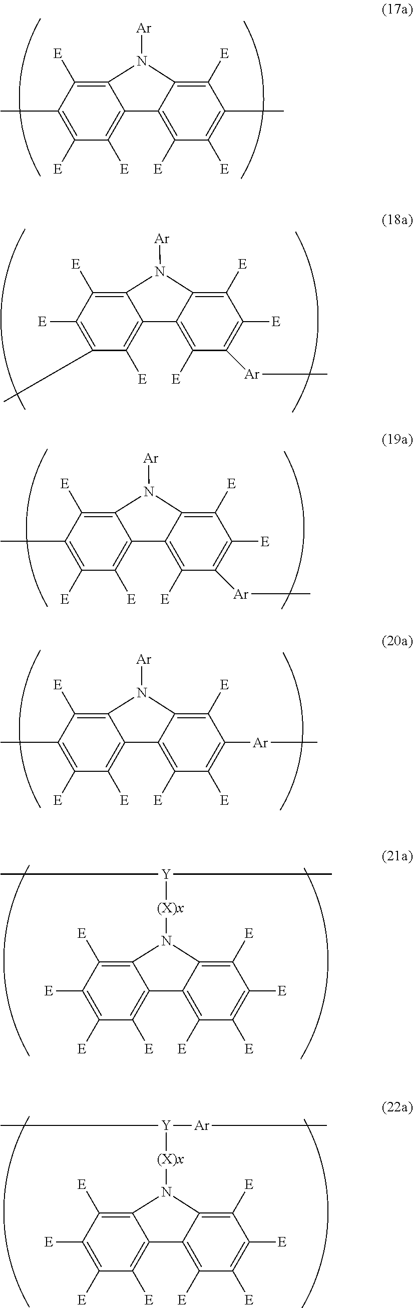

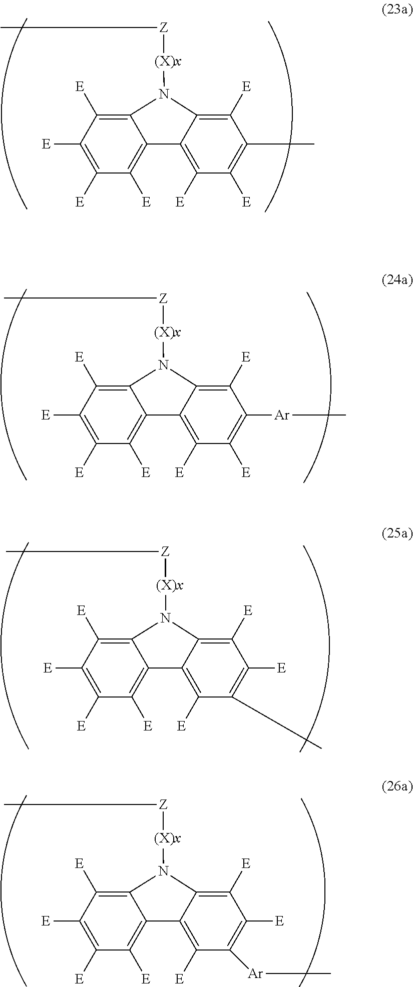

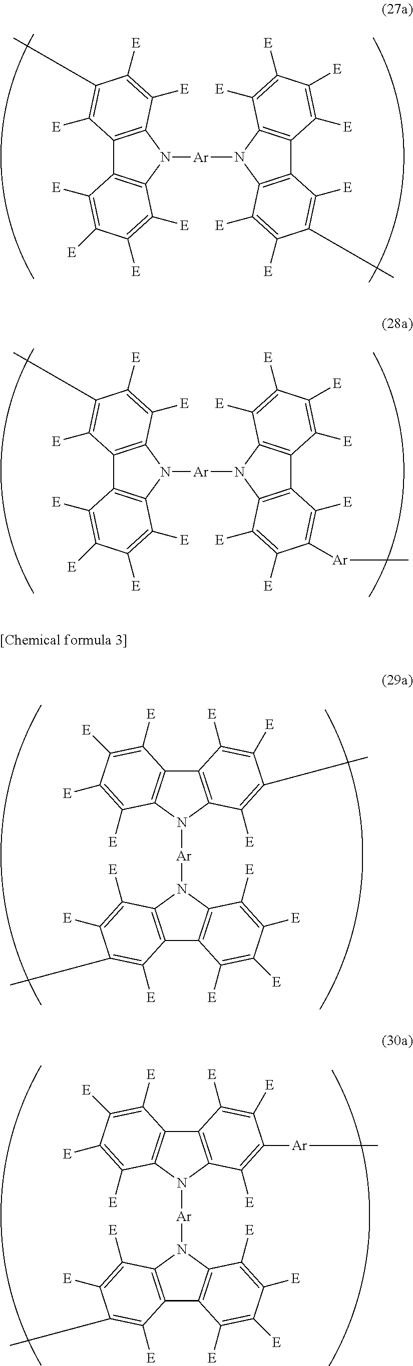

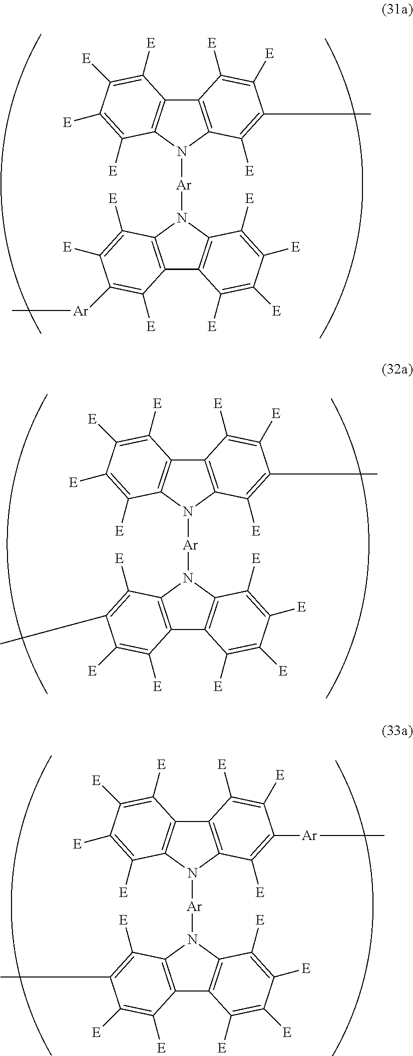

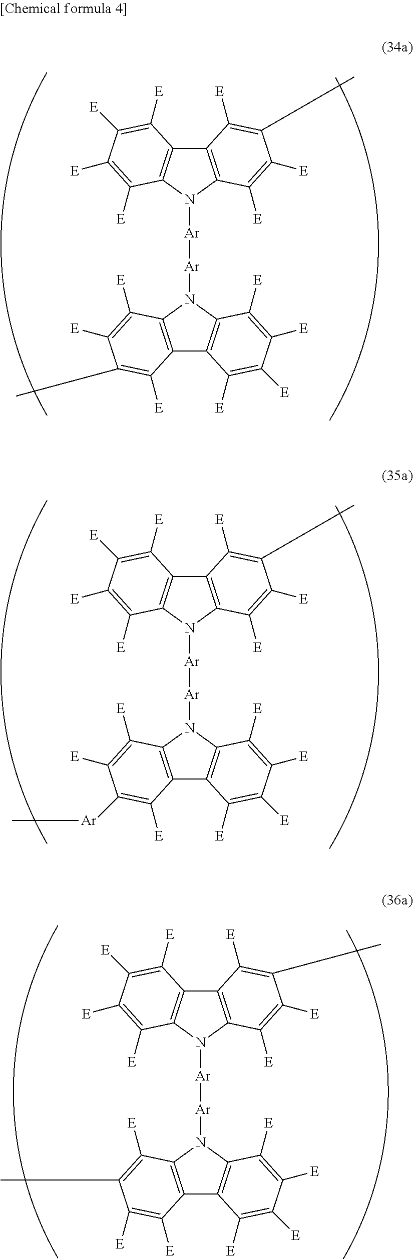

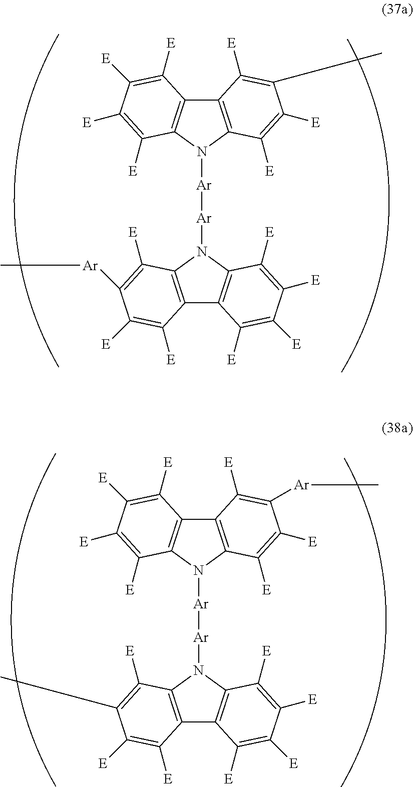

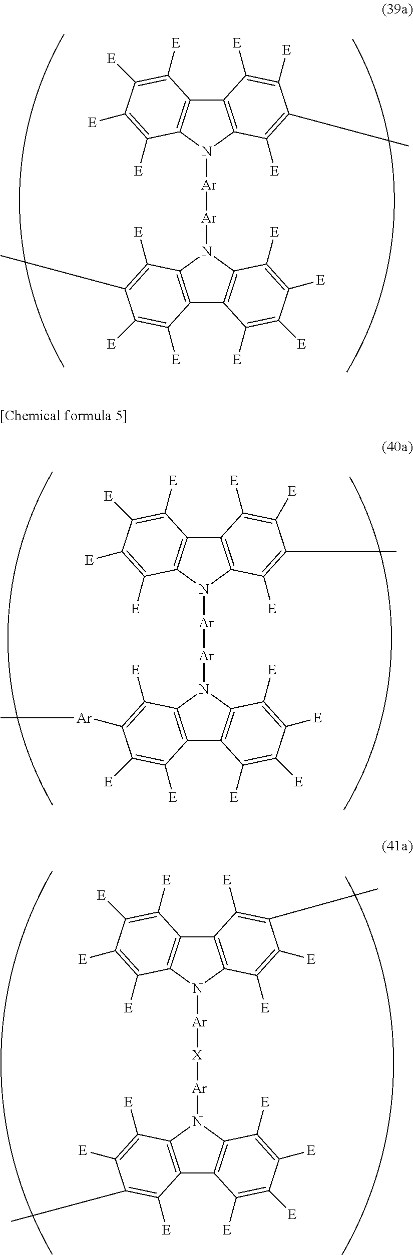

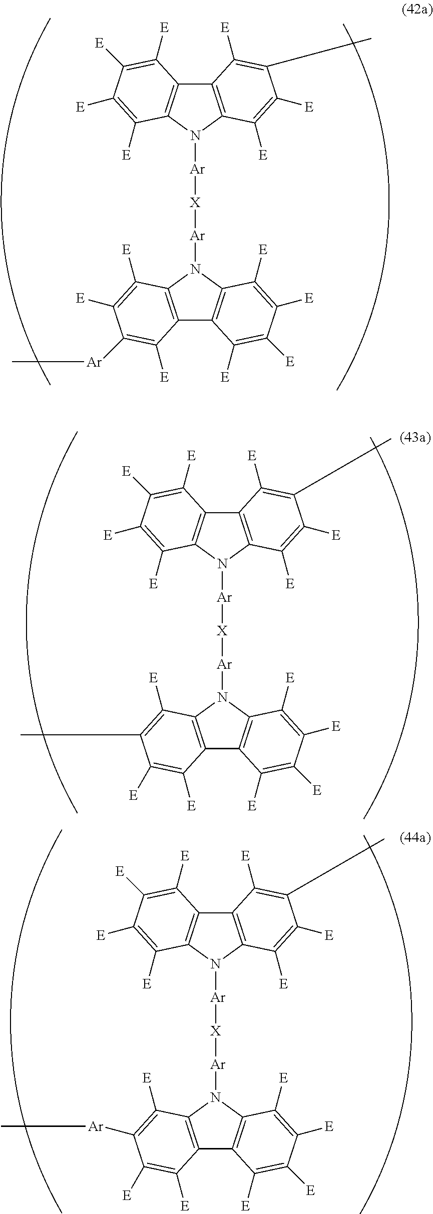

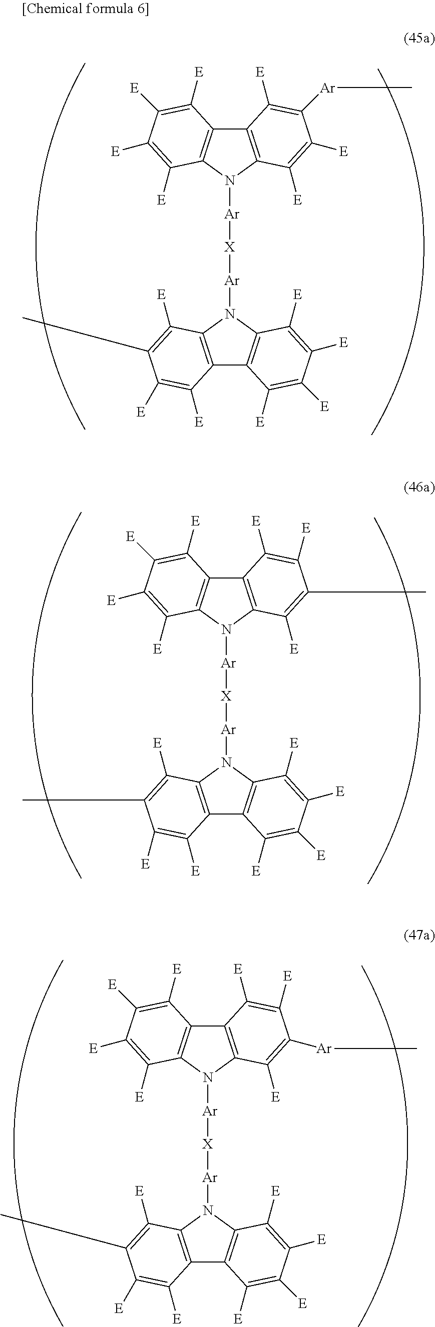

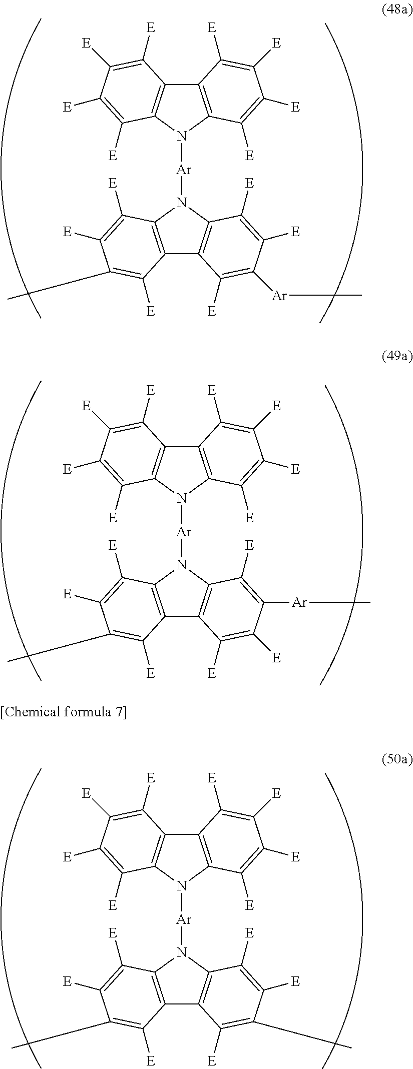

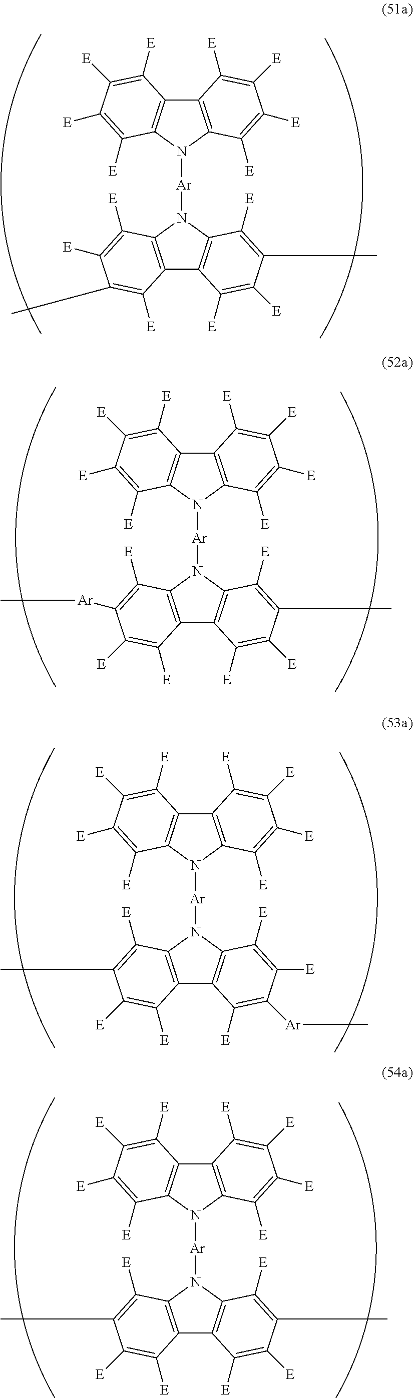

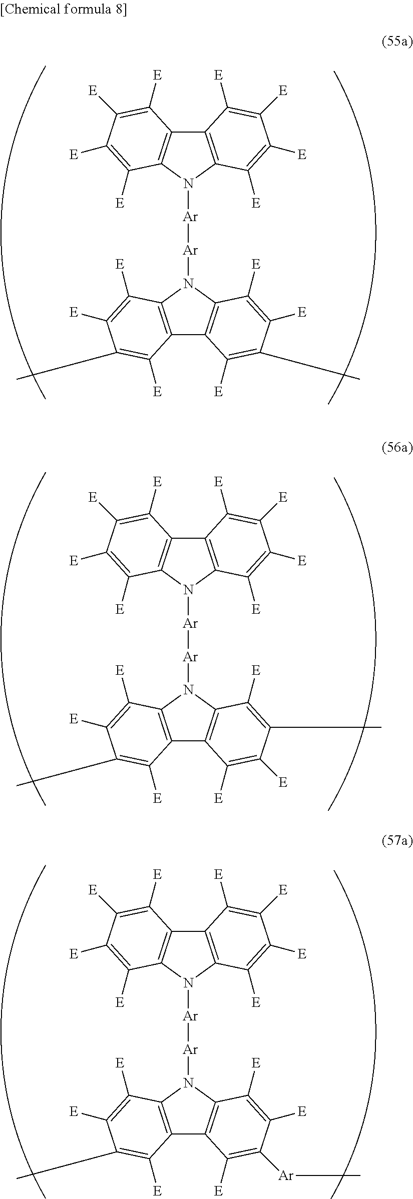

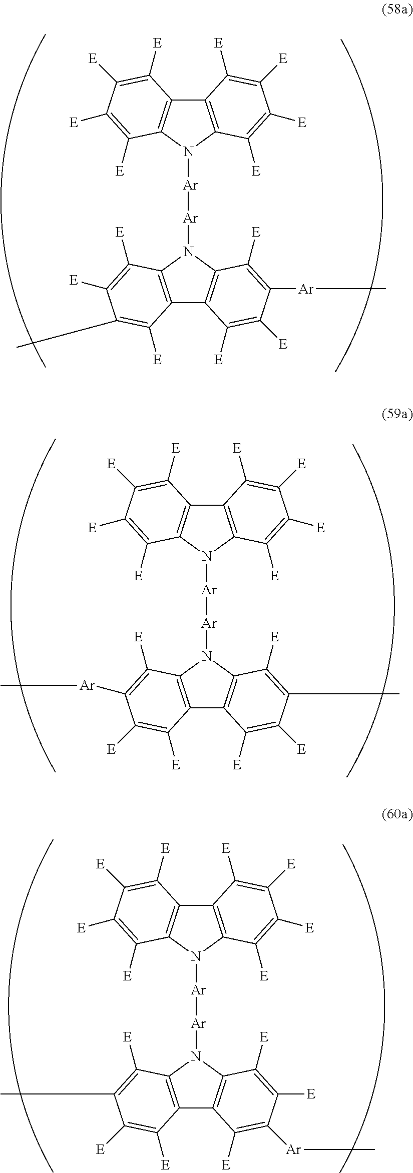

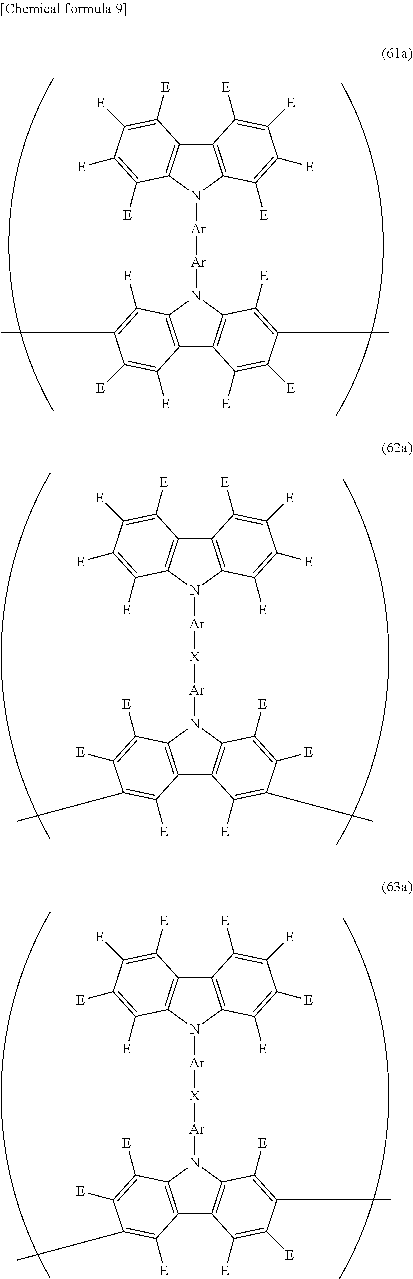

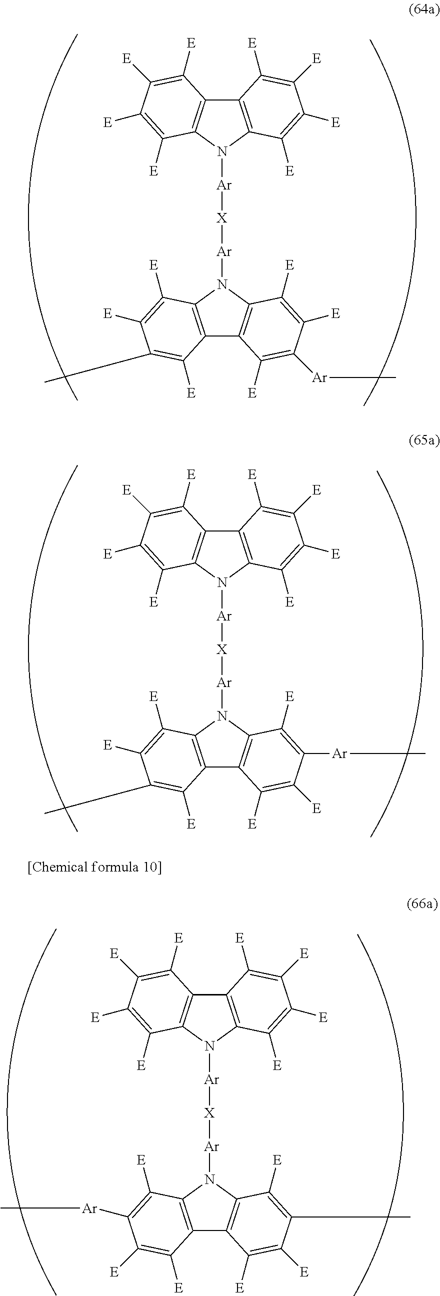

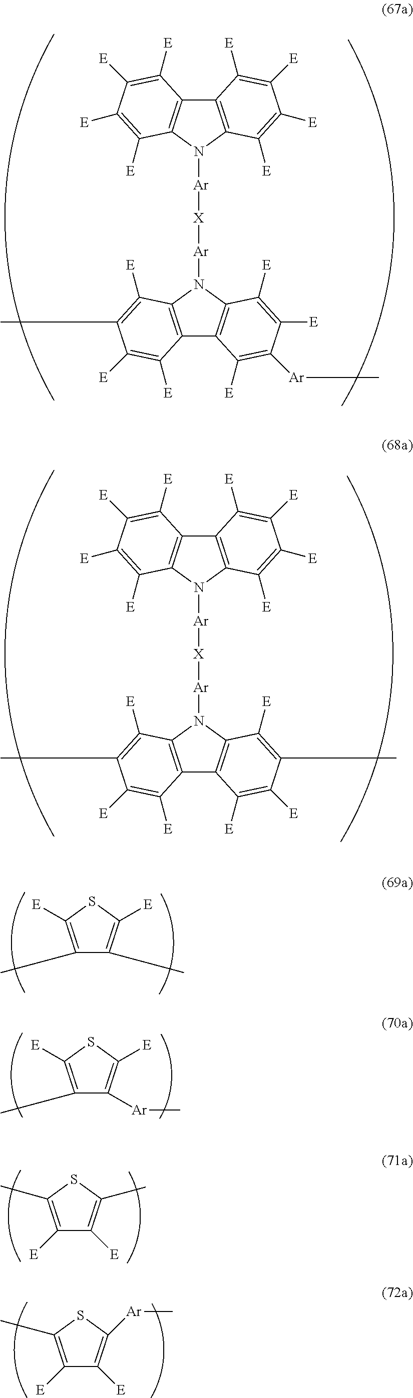

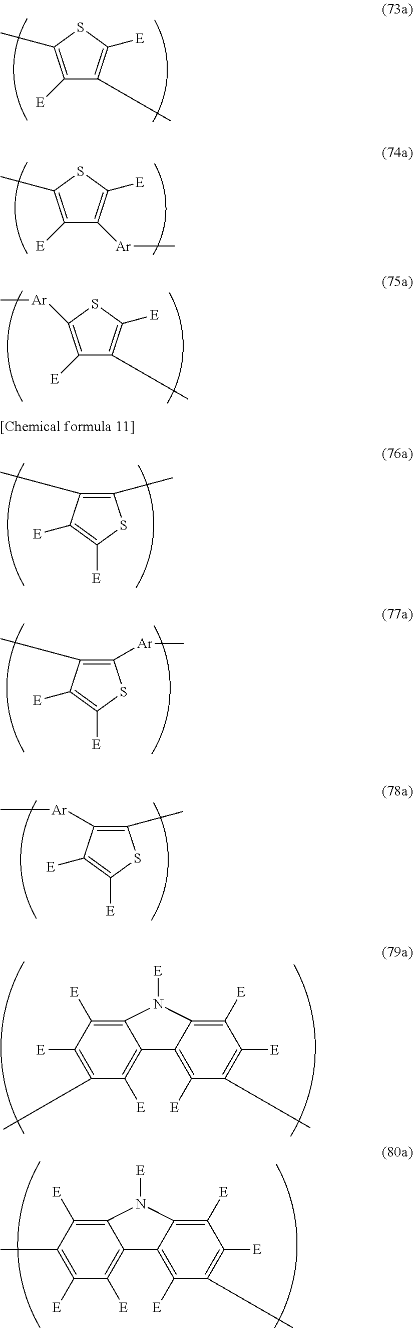

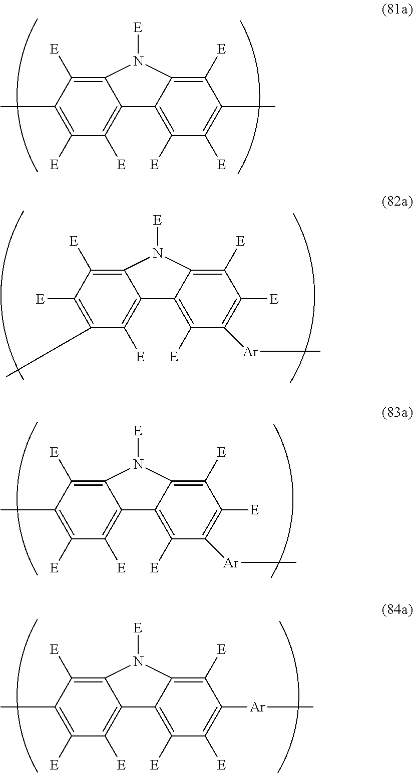

In the formulas, each E independently represents a hydrogen atom or a substituent. It is preferable that each E independently represents a group selected from the group consisting of —R¹, —OR², —OCOR⁴, —COOR⁵, —SiR⁶R⁷R⁸, groups of formulas (1) to (3) shown below, halogen atoms, and groups having a polymerizable substituent.

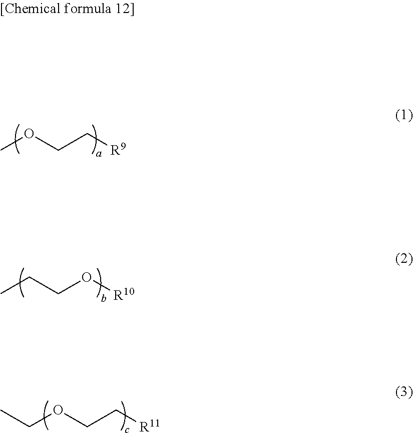

Each of R¹ to R¹¹ independently represents a hydrogen atom; a linear, cyclic or branched alkyl group of 1 to 22 carbon atoms; or an aryl group or heteroaryl group of 2 to 30 carbon atoms.

Each of R¹ to R¹¹ may have a substituent, and examples of the substituent include an alkyl group, alkoxy group, alkylthio group, aryl group, aryloxy group, arylthio group, arylalkyl group, arylalkoxy group, arylalkylthio group, arylalkenyl group, arylalkynyl group, hydroxyl group, hydroxyalkyl group, amino group, substituted amino group, silyl group, substituted silyl group, silyloxy group, substituted silyloxy group, halogen atom, acyl group, acyloxy group, imino group, amide group (—NR—COR, —CO—NR₂ (wherein R represents a hydrogen atom or an alkyl group)), imide group (—N(CO)₂Ar, —Ar(CO)₂NR (wherein R represents a hydrogen atom or an alkyl group, and Ar represents an arylene group)), carboxyl group, substituted carboxyl group, cyano group and heteroaryl group. Here, the term “substituted” means, for example, substitution with a linear, cyclic or branched alkyl group of 1 to 6 carbon atoms, or with a phenyl group or a naphthyl group.

Each of a, b and c represents an integer of 1 or greater, and preferably an integer of 1 to 4.

The groups having a polymerizable substituent are described below.

E is preferably a hydrogen atom, a substituted or unsubstituted linear, cyclic or branched alkyl group of 1 to 22 carbon atoms, or a substituted or unsubstituted aryl group or heteroaryl group of 2 to 30 carbon atoms, is more preferably a substituted or unsubstituted linear, cyclic or branched alkyl group of 1 to 22 carbon atoms, and is even more preferably an unsubstituted linear, cyclic or branched alkyl group of 1 to 22 carbon atoms.

In the above formulas, each Ar independently represents an aryl group or heteroaryl group of 2 to 30 carbon atoms, or an arylene group or heteroarylene group of 2 to 30 carbon atoms.

Each Ar may have a substituent, and examples of the substituent include the same groups as those described above for E.

In the above formulas, X and Z each independently represent a divalent linking group, and there are no particular limitations on the group. Examples include groups in which an additional hydrogen atom has been removed from any of the above E groups having one or more hydrogen atoms (but excluding groups having a polymerizable substituent), and groups shown in any of the linking group sets (A) to (C) shown below.

Further, x represents an integer of 0 to 2.

Y represents a trivalent linking group, and there are no particular limitations on the group. Examples include groups in which two additional hydrogen atoms have been removed from one of the above E groups having two or more hydrogen atoms (but excluding groups having a polymerizable substituent).

### <Linking Group Sets (A) to (C)>

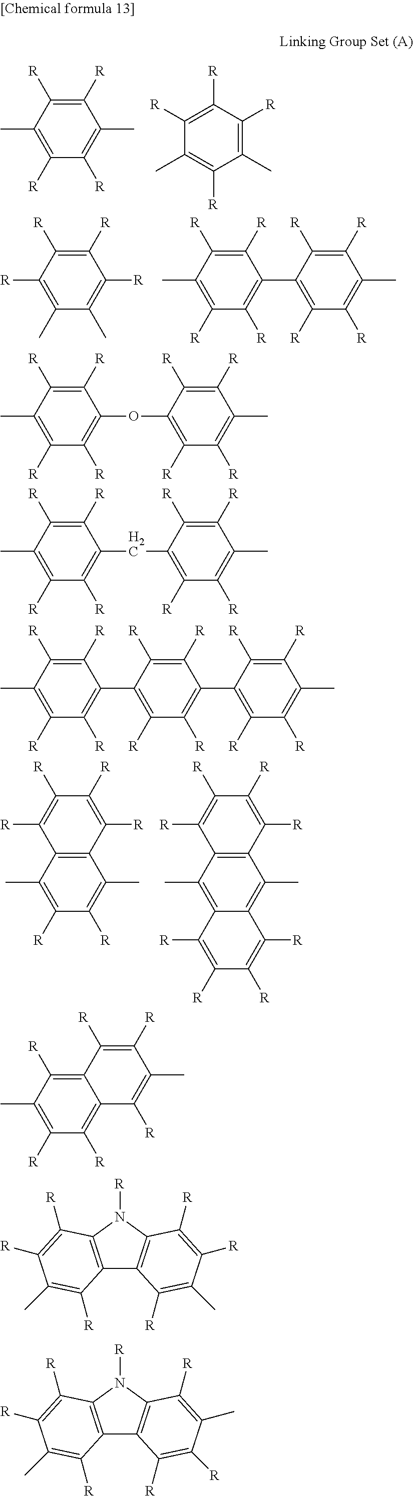

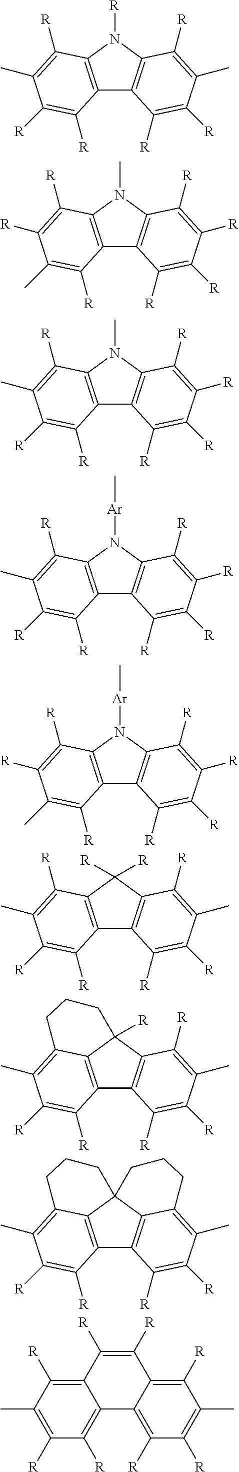

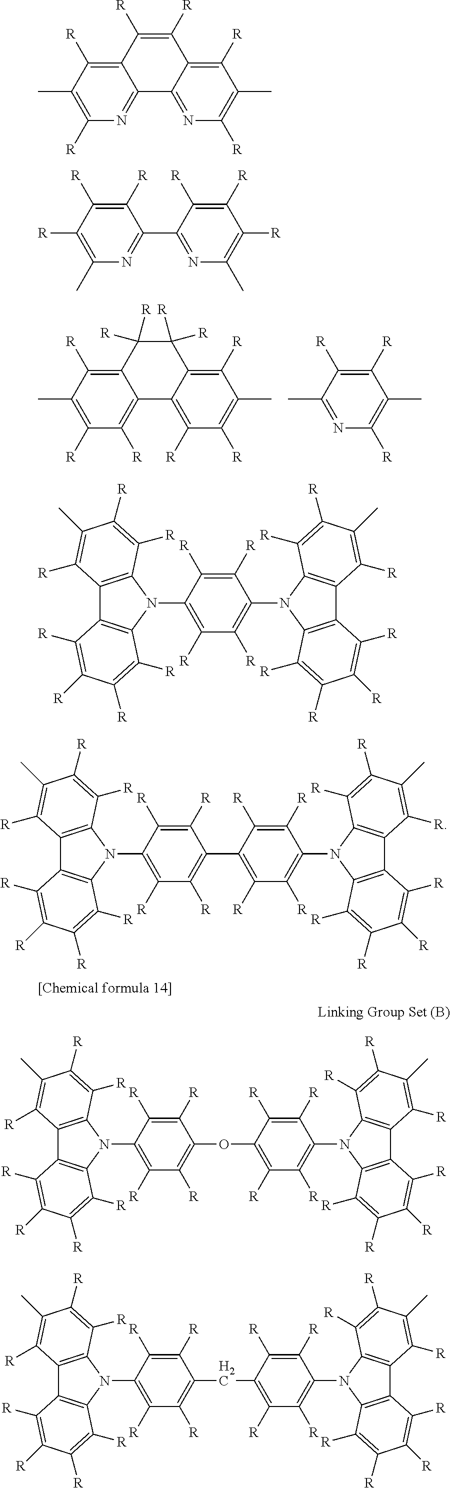

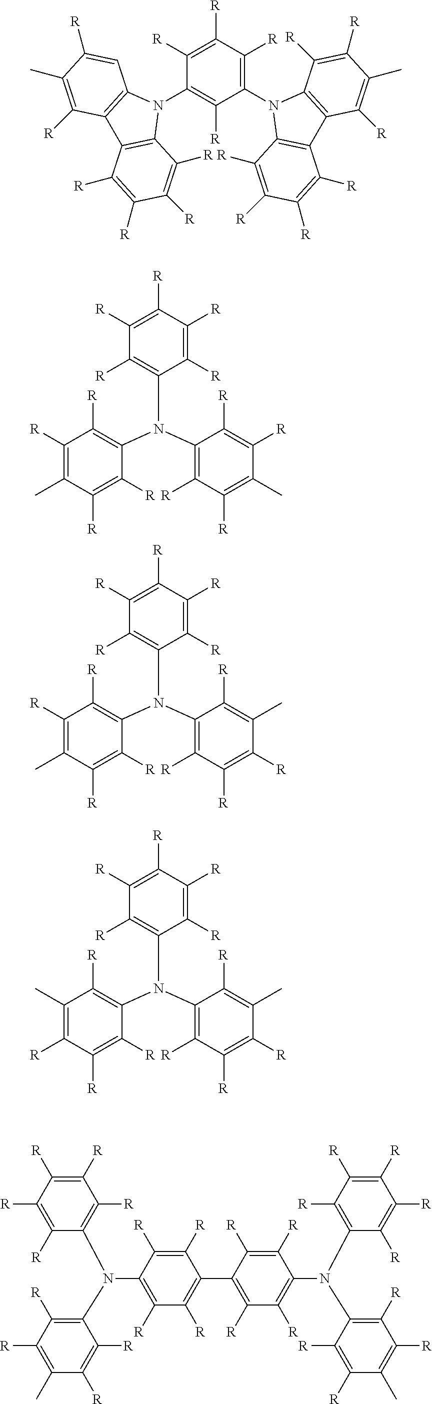

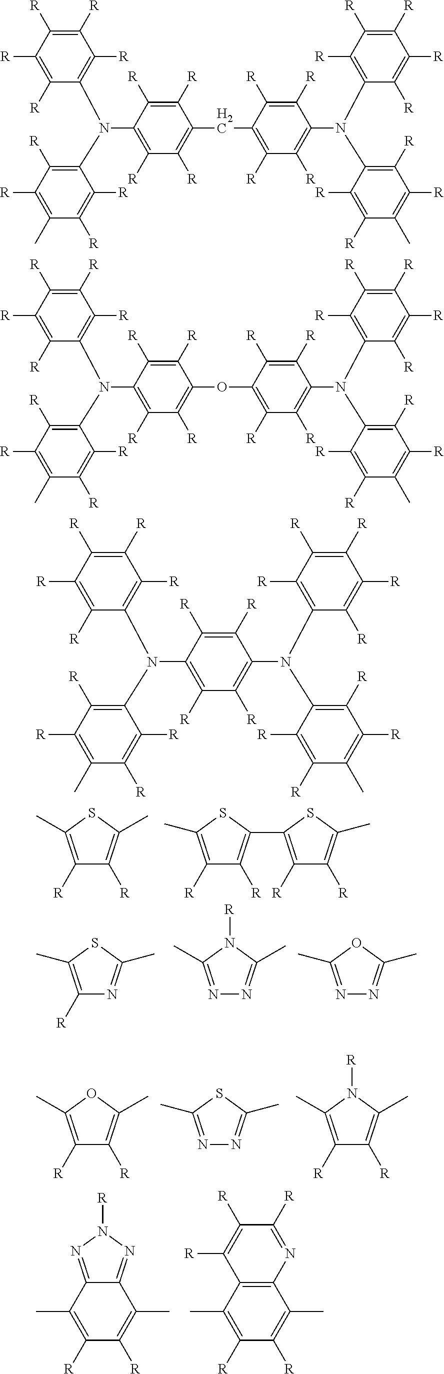

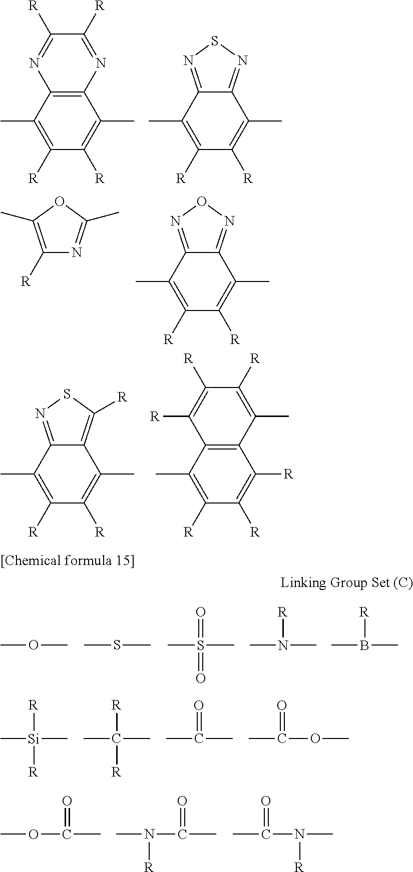

In the above formulas, examples of R include the same groups as those mentioned above for E.

In the present embodiment, examples of the halogen atoms include a fluorine atom, chlorine atom, bromine atom and iodine atom.

Examples of halogen atoms mentioned in the following description include these same groups.

In the present embodiment, examples of the alkyl group include a methyl group, ethyl group, n-propyl group, n-butyl group, n-pentyl group, n-hexyl group, n-heptyl group, n-octyl group, n-nonyl group, n-decyl group, n-undecyl group, n-dodecyl group, isopropyl group, isobutyl group, sec-butyl group, tert-butyl group, 2-ethylhexyl group, 3,7-dimethyloctyl group, cyclohexyl group, cycloheptyl group and cyclooctyl group.

Examples of alkyl groups mentioned in the following description include these same groups.

In the present embodiment, an aryl group is an atom grouping in which one hydrogen atom has been removed from an aromatic hydrocarbon, and a heteroaryl group is an atom grouping in which one hydrogen atom has been removed from an aromatic compound having a hetero atom.

Examples of the aryl group include phenyl, biphenylyl, terphenylyl, triphenylbenzenyl, naphthalenyl, anthracenyl, tetracenyl, fluorenyl and phenanthrenyl groups.

Examples of the heteroaryl group include pyridinyl, pyrazinyl, quinolinyl, isoquinolinyl, acridinyl, phenanthrolinyl, furanyl, pyrrolyl, thiophenyl, carbazolyl, oxazolyl, oxadiazolyl, thiadiazolyl, triazolyl, benzoxazolyl, benzoxadiazolyl, benzothiadiazolyl, benzotriazolyl and benzothiophenyl groups.

Examples of aryl groups and heteroaryl groups mentioned in the following description include these same groups.

In the present embodiment, an arylene group is an atom grouping in which two hydrogen atoms have been removed from an aromatic hydrocarbon, and a heteroarylene group is an atom grouping in which two hydrogen atoms have been removed from an aromatic compound having a hetero atom.

Examples of the arylene group include phenylene, biphenyl-diyl, terphenyl-diyl, triphenylbenzene-diyl, naphthalene-diyl, anthracene-diyl, tetracene-diyl, fluorene-diyl and phenanthrene-diyl groups.

Examples of the heteroarylene group include pyridine-diyl, pyrazine-diyl, quinoline-diyl, isoquinoline-diyl, acridine-diyl, phenanthroline-diyl, furan-diyl, pyrrole-diyl, thiophene-diyl, carbazole-diyl, oxazole-diyl, oxadiazole-diyl, thiadiazole-diyl, triazole-diyl, benzoxazole-diyl, benzoxadiazole-diyl, benzothiadiazole-diyl, benzotriazole-diyl and benzothiophene-diyl groups.

Examples of arylene groups and heteroarylene groups mentioned in the following description include these same groups.

From the viewpoint of achieving superior hole transport properties, the structural unit having hole transport properties is preferably one of the structural units (1a) to (8a), (15a) to (20a), (23a) to (47a), and (69a) to (84a), is more preferably one of the structural units (1a) to (8a), (15a) to (20a), and (69a) to (84a), and is even more preferably one of the structural units (1a) to (8a), (15a) to (20a), and (79a) to (84a). These structural units are also preferred in terms of enabling easier synthesis of the charge transport polymer or oligomer using the corresponding monomers.

Specific examples of preferred structural units having hole transport properties include the structural units (a1) to (a6) shown below.

<Structural Units (a1) to (a6)>

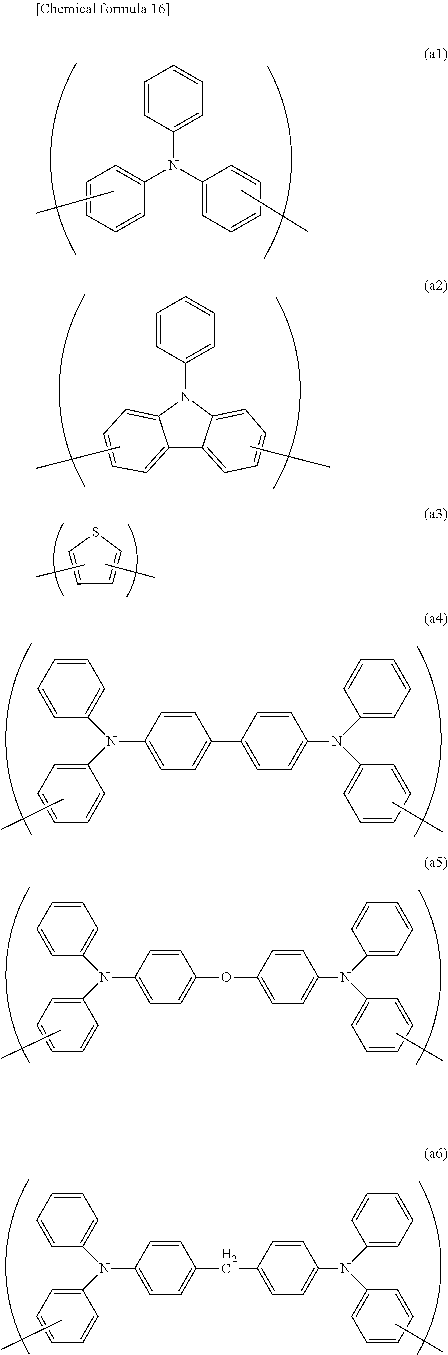

In the formulas, the phenyl groups and phenylene groups, and the thiophene-diyl group may each have a substituent, and examples of the substituent include the same groups as those described above for E. When a substituent exists, the substituent is preferably a linear, cyclic or branched alkyl group of 1 to 22 carbon atoms, or an aryl group or heteroaryl group of 2 to 30 carbon atoms, and is more preferably a linear, cyclic or branched alkyl group of 1 to 22 carbon atoms.

### (Copolymerization Units)

In order to adjust the electrical characteristics, the charge transport polymer or oligomer may also have, besides the unit(s) described above, a copolymerization unit composed of an aforementioned arylene group or heteroarylene group, or a structural unit represented by one of the linking group sets (A) and (B) above. The charge transport polymer or oligomer may have only one type of other copolymerization unit, or may have two or more types.

### (Branched Structure)

The charge transport polymer or oligomer may be a linear polymer or oligomer having no branch chains (side chains), or may be a branched polymer or oligomer having one or more branch chains Each branch chain has at least one structural unit, and preferably two or more structural units, which constitute part of the charge transport polymer or oligomer.

A combination of a linear polymer or oligomer and a branched polymer or oligomer may also be used. From the viewpoint of facilitating more precise control of the molecular weight and the physical properties of the composition, a linear polymer or oligomer is preferred, whereas from the viewpoint of making it easier to increase the molecular weight, a branched polymer or oligomer is preferred. A branched polymer or oligomer is also preferred from the viewpoint of enhancing the durability of the organic electronic element.

If the charge transport polymer or oligomer has no branch chains, then that means the charge transport polymer or oligomer will have two terminals. A “terminal” refers to an end of the polymer or oligomer chain.

If the charge transport polymer or oligomer has a branch chain, then that means the charge transport polymer or oligomer has a branched portion on the polymer or oligomer chain, and has three or more terminals. For example, the charge transport polymer or oligomer may have, as a branched portion, a structural unit that functions as the branch origin (hereafter also referred to as a “branch origin structural unit”). The charge transport polymer or oligomer may have only one type of branch origin structural unit, or may have two or more types of these structural units.

The branch origin structural unit is a trivalent or higher structural unit, and from the viewpoint of durability, is preferably a trivalent to hexavalent structural unit, and more preferably a trivalent or tetravalent structural unit. As mentioned above, the charge transport polymer or oligomer preferably has a structural unit having hole transport properties at least as a divalent structural unit. The charge transport polymer or oligomer may also have a unit having hole transport properties as a branch origin structural unit.

Specific examples of the branch origin structural unit include structural units (1b) to (11b) shown below. The structural units (2b) to (4b) correspond with structural units having an aromatic amine structure, and the structural units (5b) to (8b) correspond with structural units having a carbazole structure.

<Structural Units (1b) to (11b)>

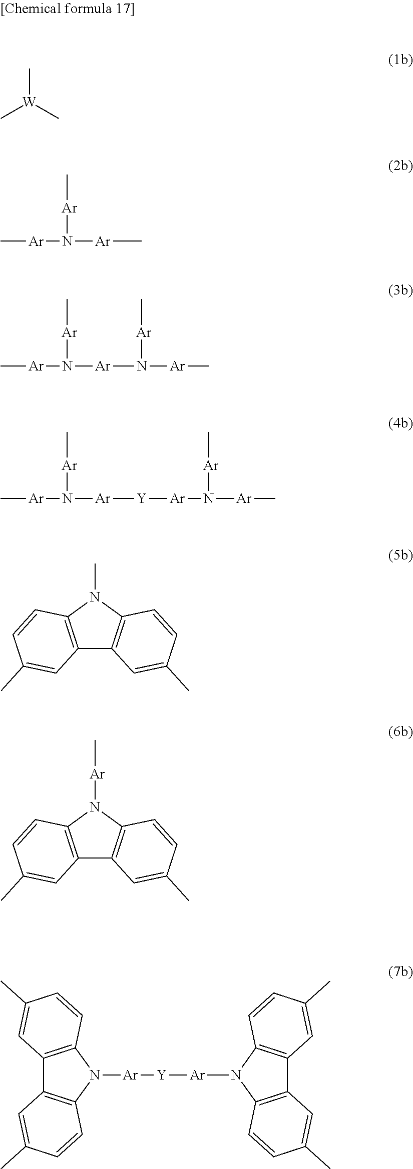

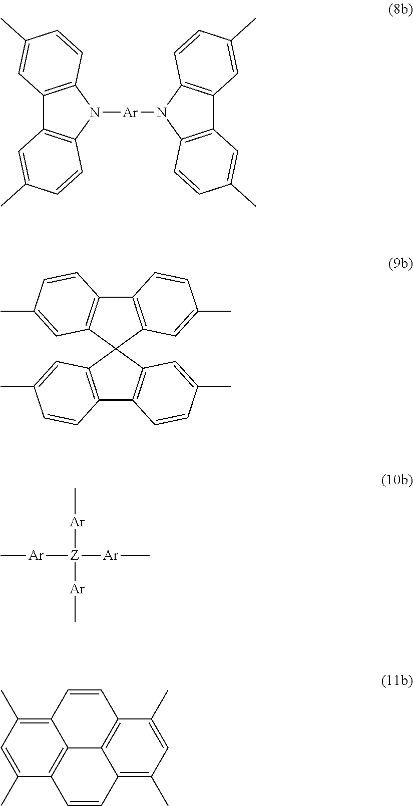

In the above formulas, W represents a trivalent linking group, and examples include groups in which an additional one hydrogen atom has been removed from an arylene group or heteroarylene group of 2 to 30 carbon atoms.

Each Ar independently represents a divalent linking group, and for example, independently represents an arylene group or heteroarylene group of 2 to 30 carbon atoms. Ar is preferably an arylene group, and more preferably a phenylene group.

Y represents a divalent linking group, and there are no particular limitations on the group. Examples include groups in which an additional hydrogen atom has been removed from any of the above E groups having one or more hydrogen atoms (but excluding groups having a polymerizable substituent), and groups shown in the above linking group set (C).

Z represents a carbon atom, silicon atom or phosphorus atom.

Each of the structural units (1b) to (11b) may have a substituent, and examples of the substituent include the same groups as those mentioned above for E.

### (Terminal Structures)

The charge transport polymer or oligomer has a condensed polycyclic aromatic hydrocarbon moiety at least at one terminal. The charge transport polymer or oligomer may have only one type of condensed polycyclic aromatic hydrocarbon moiety, or may have two or more types of these moieties. It is thought that by including the condensed polycyclic aromatic hydrocarbon moiety at a terminal, the electron transport properties of the charge transport polymer or oligomer can be improved, namely the stability relative to electrons is improved, thus resulting in superior performance as an organic electronic material.

In the present embodiment, the “condensed polycyclic aromatic hydrocarbon” is a hydrocarbon compound which has three or more benzene rings, and may also have a ring besides the benzene rings. Each ring has two or more atoms in common with another ring. Further, the “condensed polycyclic aromatic hydrocarbon moiety” is an atom grouping in which one hydrogen atom has been removed from the condensed polycyclic aromatic hydrocarbon. The condensed polycyclic aromatic hydrocarbon contained in the condensed polycyclic aromatic hydrocarbon moiety may be substituted or unsubstituted, and in one preferred embodiment, is unsubstituted.

Examples of the condensed polycyclic aromatic hydrocarbon moiety include moieties in which the benzene rings are linked linearly (for example, an anthracene moiety), and moieties in which the benzene rings are linked in a non-linear manner (for example, a phenanthrene moiety). Further, examples of the condensed polycyclic aromatic hydrocarbon moiety include moieties in which the benzene rings are linked directly (for example, an anthracene moiety), and moieties in which the benzene rings are linked via another cyclic hydrocarbon (for example, a fluoranthene moiety).

From the viewpoint of the solubility in solvents during synthesis of the polymer or oligomer, the number of benzene rings included in the condensed ring structure of the condensed polycyclic aromatic hydrocarbon moiety is preferably not more than 8, more preferably not more than 7, and even more preferably 6 or fewer. Further, from the viewpoint of obtaining superior lifespan characteristics, the number of benzene rings is preferably not more than 6, and may be 5 or fewer. From the viewpoint of obtaining superior lifespan characteristics, the number of benzene rings is preferably at least 3. For example, when the charge transport polymer or oligomer is used in a hole transport layer, the number of benzene rings is preferably 4 or greater.

Examples of substituents that the condensed polycyclic aromatic hydrocarbon may have include linear, cyclic or branched alkyl groups (preferably of 1 to 20 carbon atoms, more preferably 1 to 15 carbon atoms, and even more preferably 1 to 10 carbon atoms), linear, cyclic or branched alkoxy groups (preferably of 1 to 20 carbon atoms, more preferably 1 to 15 carbon atoms, and even more preferably 1 to 10 carbon atoms), and a phenyl group. From the viewpoints of achieving superior solubility and stability, a linear, cyclic or branched alkyl group, or a phenyl group is preferred.

In one preferred embodiment, the condensed polycyclic aromatic hydrocarbon is selected from the group consisting of anthracene (3), tetracene (4), pentacene (5), phenanthrene (3), chrysene (4), triphenylene (4), tetraphene (4), pyrene (4), picene (5), pentaphene (5), perylene (5), pentahelicene (5), hexahelicene (6), heptahelicene (7), coronene (7), fluoranthene (3), acephenanthrylene (3), aceanthrene (3), aceanthrylene (3), pleiadene (4), tetraphenylene (4), cholanthrene (4), dibenzanthracene (5), benzopyrene (5), rubicene (5), hexaphene (6), hexacene (6), trinaphthylene (7), heptaphene (7), heptacene (7), pyranthrene (8) and ovalene (10). In the above list, the numbers in parentheses indicate the numbers of benzene rings contained in the condensed polycyclic aromatic hydrocarbons. From the viewpoint of improving the characteristics, the condensed polycyclic aromatic hydrocarbon preferably includes one type of compound selected from the group consisting of anthracene, tetracene, pentacene, phenanthrene, chrysene, triphenylene, tetraphene, pyrene, picene, pentaphene, perylene, pentahelicene, hexahelicene, heptahelicene and coronene. Although not a particular limitation, when the condensed polycyclic aromatic hydrocarbon includes one type of compound selected from the group consisting of anthracene, phenanthrene, tetracene, tetraphene, chrysene, triphenylene, pyrene, pentacene, pentaphene and perylene, excellent durability can be more easily obtained, which is more preferred. In a particularly preferred embodiment, the condensed polycyclic aromatic hydrocarbon includes one type of compound selected from the group consisting of anthracene, triphenylene, pyrene and pentacene.

Examples of the condensed polycyclic aromatic hydrocarbon moiety include moieties represented by a structure (1c) shown below.

<Structure (1c)>

Ar¹) [Chemical formula 18]

In the above formula, Ar¹ represents a condensed polycyclic aromatic hydrocarbon group having 3 to 8, and preferably 3 to 6, benzene rings. Ar¹ may be unsubstituted, or may have a substituent. Examples of the substituent include unsubstituted or substituted linear, cyclic or branched alkyl groups (preferably of 1 to 20 carbon atoms, more preferably 1 to 15 carbon atoms, and even more preferably 1 to 10 carbon atoms), substituted or unsubstituted linear cyclic or branched alkoxy groups (preferably of 1 to 20 carbon atoms, more preferably 1 to 15 carbon atoms, and even more preferably 1 to 10 carbon atoms), and substituted or unsubstituted phenyl groups. In one embodiment, Ar¹ is preferably unsubstituted.

Specific examples of preferred condensed polycyclic aromatic hydrocarbon moieties include structures (c1) to (c17) shown below.

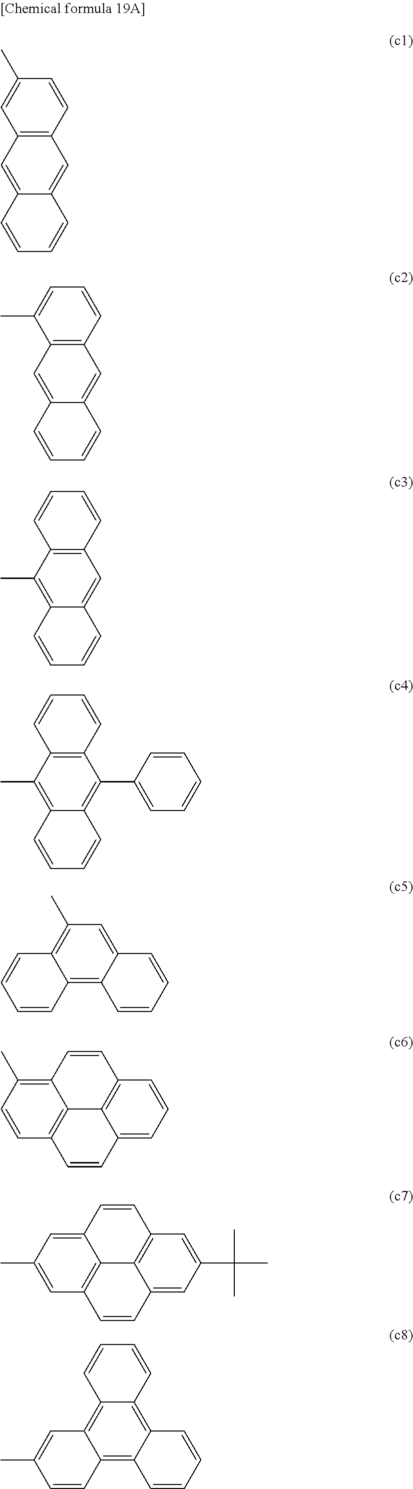

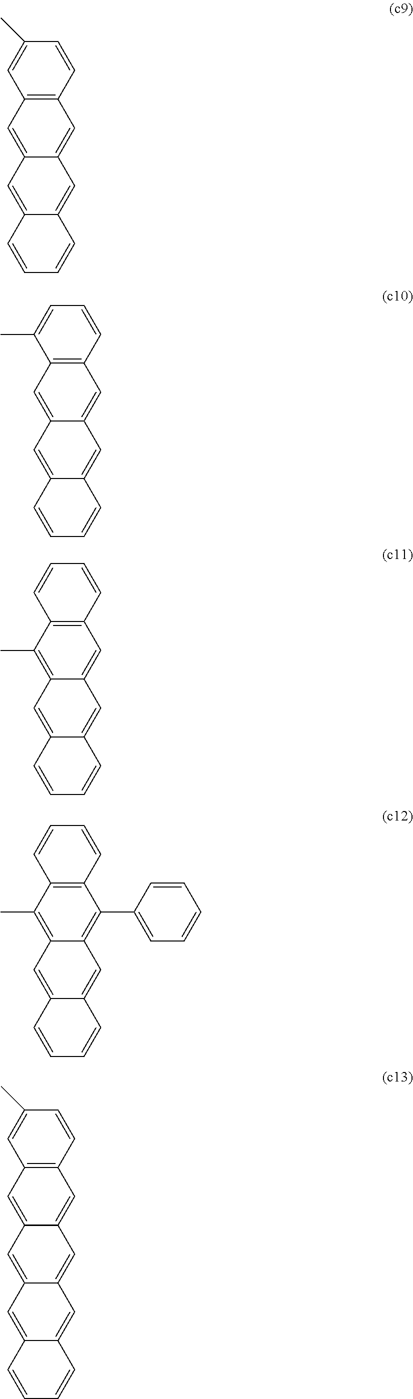

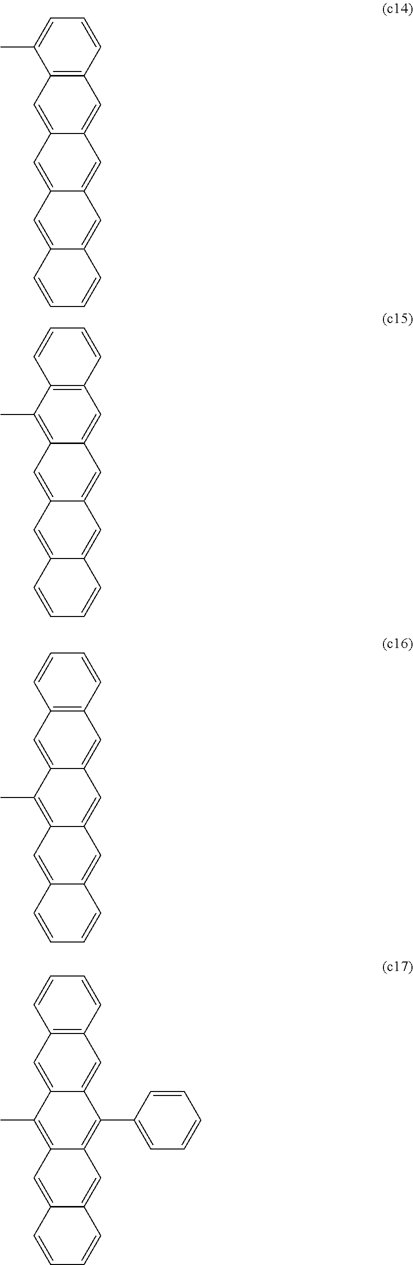

An example of the terminal structural unit having the condensed polycyclic aromatic hydrocarbon moiety is a structural unit (1c) shown below. This terminal structural unit is a monovalent structural unit.

<Structural Unit (1c)>

ArₙAr¹ [Chemical formula 19B]

In the formula, Ar¹ is as defined above. Ar represents an arylene group or heteroarylene group of 2 to 30 carbon atoms, and n represents 0 or 1. One example of Ar is a phenylene group.

In one embodiment, the charge transport polymer or oligomer may also have a moiety besides the condensed polycyclic aromatic hydrocarbon moiety (hereafter also referred to as an “other terminal moiety”) at a terminal. The charge transport polymer or oligomer may have only one type of other terminal moiety, or may have two or more types. There are no particular limitations on the other terminal moiety. Examples include structural units represented by any of the above formulas (1a) to (84a) (in which E is bonded to one of the terminal bonding sites), or moieties having an aromatic hydrocarbon structure or an aromatic compound structure. Specific examples of the moieties having an aromatic hydrocarbon structure or an aromatic compound structure include a structure (1d) shown below. The structure (1d) has a structure different from the condensed polycyclic aromatic hydrocarbon moiety. In other words, structures having a condensed polycyclic aromatic hydrocarbon moiety are excluded from the structure (1d).

<Structure (1d)>

Ar²) [Chemical formula 20A]

In the formula, Ar² represents an aryl group or heteroaryl group of 2 to 30 carbon atoms. From the viewpoint of facilitating the introduction of a polymerizable substituent at the terminal, Ar² is typically an aryl group, and preferably a phenyl group. Ar² may have a substituent, and examples of the substituent include the same groups as those mentioned above for E. When a substituent exists, the substituent is preferably a substituted or unsubstituted linear, cyclic or branched alkyl group of 1 to 22 carbon atoms, or a group having a polymerizable substituent.

Examples of terminal structural units having other terminal moieties include a structural unit (1d) shown below.

<Structural Unit (1d)>

ArₙAr² [Chemical formula 20B]

In the formula, Ar² is as defined above. Ar represents an arylene group or heteroarylene group of 2 to 30 carbon atoms, and n represents 0 or 1. One example of Ar is a phenylene group.

From the viewpoint of improving the characteristics of the organic electronic element, the proportion of condensed polycyclic aromatic hydrocarbon moieties across all of the terminals of the charge transport polymer or oligomer is preferably at least 25%, more preferably at least 30%, and even more preferably at least 35%, relative to the total number of terminals. There are no particular limitations on the upper limit, which may be 100% or less.

This proportion across all of the terminals can be determined from the amounts (molar ratios) of the monomers corresponding with the terminal structural units used during synthesis of the charge transport polymer or oligomer.

If the charge transport polymer or oligomer has one or more other terminal moieties, then from the viewpoint of improving the characteristics of the organic electronic element, the proportion of these other terminal moieties across all of the terminals is preferably not more than 75%, more preferably not more than 70%, and even more preferably 65% or less, relative to the total number of terminals. There are no particular limitations on the lower limit, but if consideration is given to introduction of the polymerizable substituent described below, and the introduction of substituents for the purposes of improving the film formability and the wettability and the like, the lower limit is typically at least 5%.

### (Polymerizable Substituent)

A polymerizable substituent refers to a substituent that can form a bond between two or more molecules by causing a polymerization reaction. The polymerization reaction yields a cured product of the charge transport compound, and changes the solubility of the charge transport compound in solvents, making it easier to form stacked structures.

There are no particular limitations on the position at which the polymerizable substituent exists in the charge transport polymer or oligomer, and any position that enables the formation of a bond between two or more molecules via a polymerization reaction is suitable. The charge transport polymer or oligomer may have a polymerizable substituent within a terminal structural unit, may have a polymerizable substituent within a structural unit other than a terminal unit, or may have polymerizable substituents within both a terminal structural unit and a structural unit other than a terminal unit. The charge transport polymer or oligomer preferably has a polymerizable substituent at least within a terminal structural unit.

Examples of the polymerizable substituent include groups having a carbon-carbon multiple bond, groups having a cyclic structure (excluding groups having an aromatic heterocyclic structure), groups having an aromatic heterocyclic structure, groups containing a siloxane derivative, and combinations of groups capable of forming an ester linkage or an amide linkage.

Examples of the groups having a carbon-carbon multiple bond include groups having a carbon-carbon double bond and groups having a carbon-carbon triple bond, and specific examples include an acryloyl group, acryloyloxy group, acryloylamino group, methacryloyl group, methacryloyloxy group, methacryloylamino group, vinyloxy group, vinylamino group, and stilyl group; alkenyl groups such as an allyl group, butenyl group and vinyl group (but excluding the groups mentioned above); and alkynyl groups such as an ethynyl group.

Examples of the groups having a cyclic structure include groups having a cyclic alkyl structure, groups having a cyclic ether structure, lactone groups (groups having a cyclic ester structure), and lactam groups (groups having a cyclic amide structure), and specific examples include a cyclopropyl group, cyclobutyl group, cardene group (1,2-dihydrobenzocyclobutene group), epoxy group (oxiranyl group), oxetane group (oxetanyl group), diketene group, episulfide group, α-lactone group, β-lactone group, α-lactam group and β-lactam group.

Examples of the groups having an aromatic heterocyclic structure include a furanyl group, pyrrolyl group, thiophenyl group and silolyl group.

Examples of combinations of groups capable of forming an ester linkage or an amide linkage include a combination of a carboxyl group and a hydroxyl group, and a combination of a carboxyl group and an amino group.

From the viewpoint of achieving superior curability, the number of polymerizable substituents per one molecule of the charge transport polymer or oligomer is preferably at least two, and more preferably three or greater. From the viewpoint of the stability of the charge transport polymer or oligomer, the number of polymerizable substituents is preferably not more than 1,000, and more preferably 500 or fewer.

The charge transport polymer or oligomer may contain the “polymerizable substituent” in the form of a “group having a polymerizable substituent”. From the viewpoints of increasing the degree of freedom associated with the polymerizable substituent and facilitating the polymerization reaction, it is preferable that the group having a polymerizable substituent has an alkylene portion, with the polymerizable substituent bonded to this alkylene portion. Examples of the alkylene portion include linear alkylene portions such as methylene, ethylene, propylene, butylene, pentylene, hexylene, heptylene and octylene. The alkylene portion preferably has 1 to 8 carbon atoms.

From the viewpoint of enhancing the affinity with hydrophilic electrodes of ITO or the like, it is preferable that the group having the polymerizable substituent has a hydrophilic portion, with the polymerizable substituent bonded to this hydrophilic portion. Examples of the hydrophilic portion include linear hydrophilic portions including oxyalkylene structures such as an oxymethylene structure and an oxyethylene structure, and polyalkyleneoxy structures such as a polyoxymethylene structure and a polyoxyethylene structure. The hydrophilic portion preferably has 1 to 8 carbon atoms.

Further, from the viewpoint of making it easier to prepare the charge transport polymer or oligomer, the linking portion in the group having the polymerizable substituent, between the alkylene portion or hydrophilic portion and the polymerizable substituent and/or the atom grouping having the ability to transport an electric charge, may include an ether linkage or an ester linkage or the like.

Specific examples of the group having the polymerizable substituent include the substituent sets (A) to (N) shown below. In the present embodiment, examples of the “group having the polymerizable substituent” include the “polymerizable substituent” itself.

### <Substituent Sets (A) to (N)>

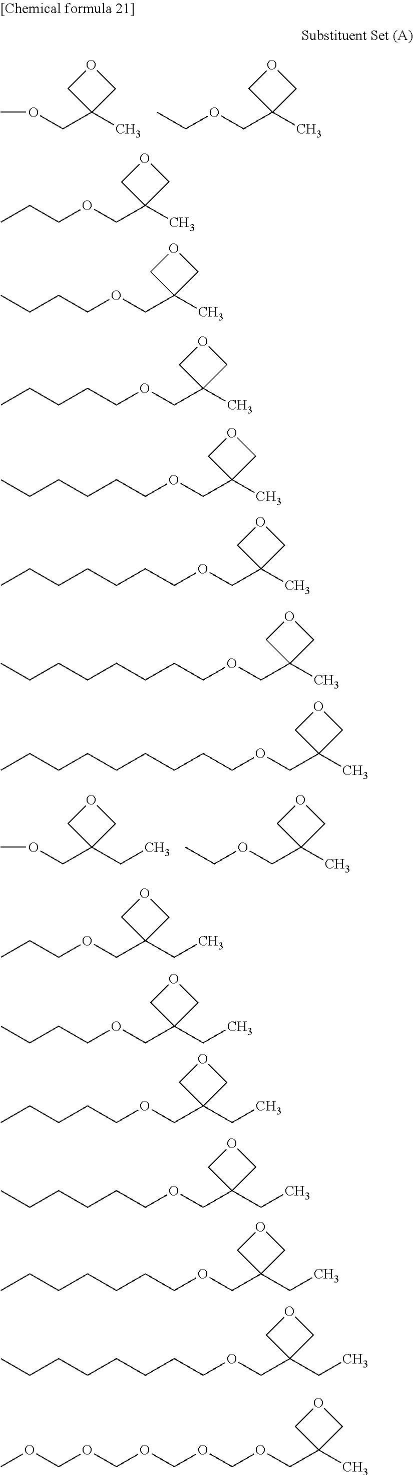

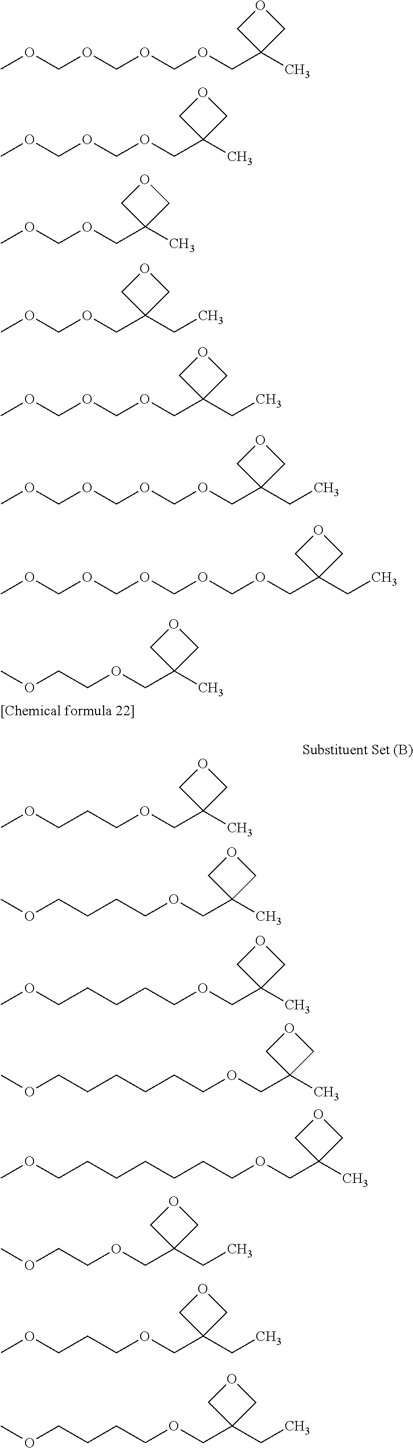

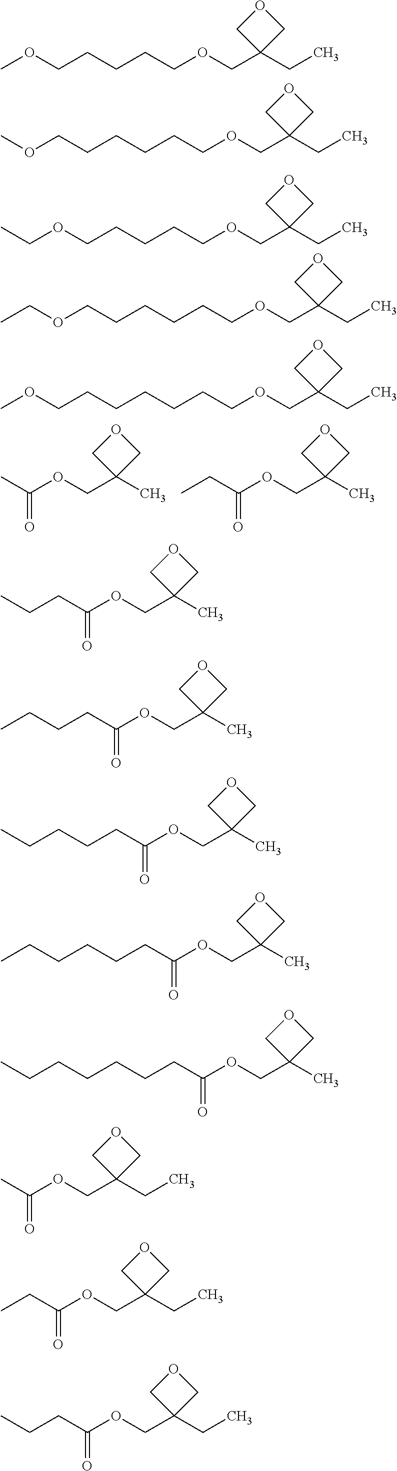

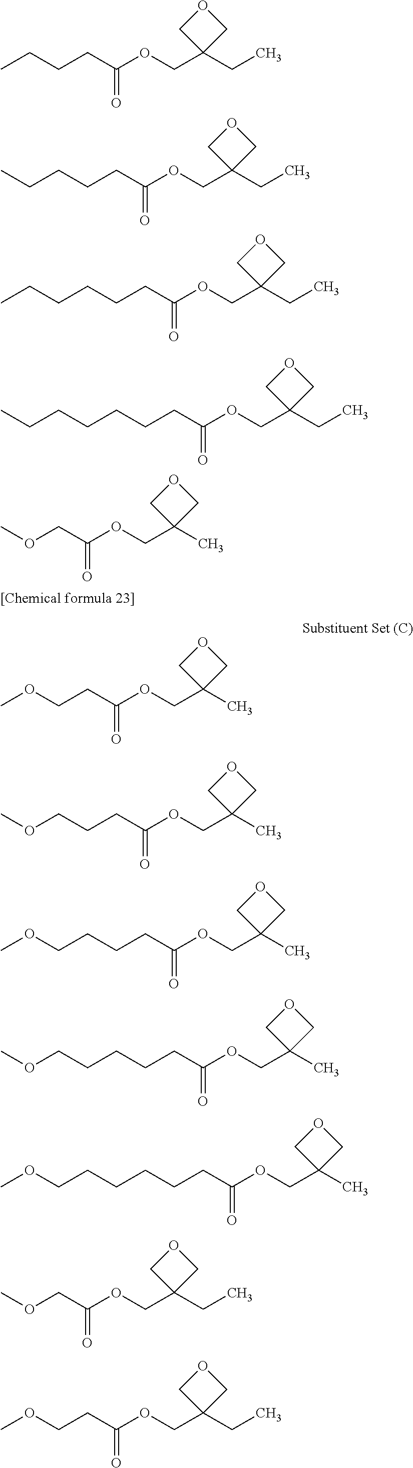

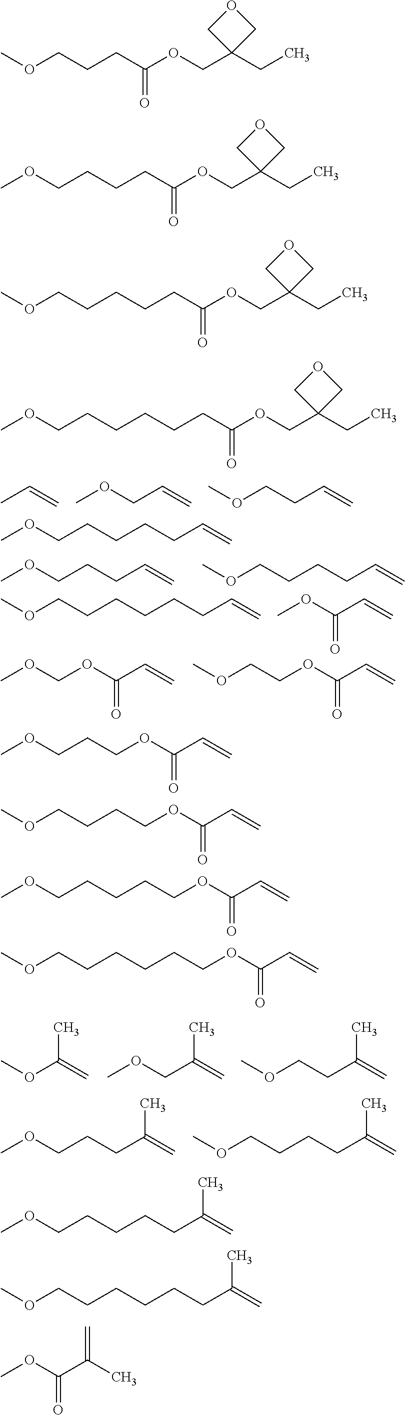

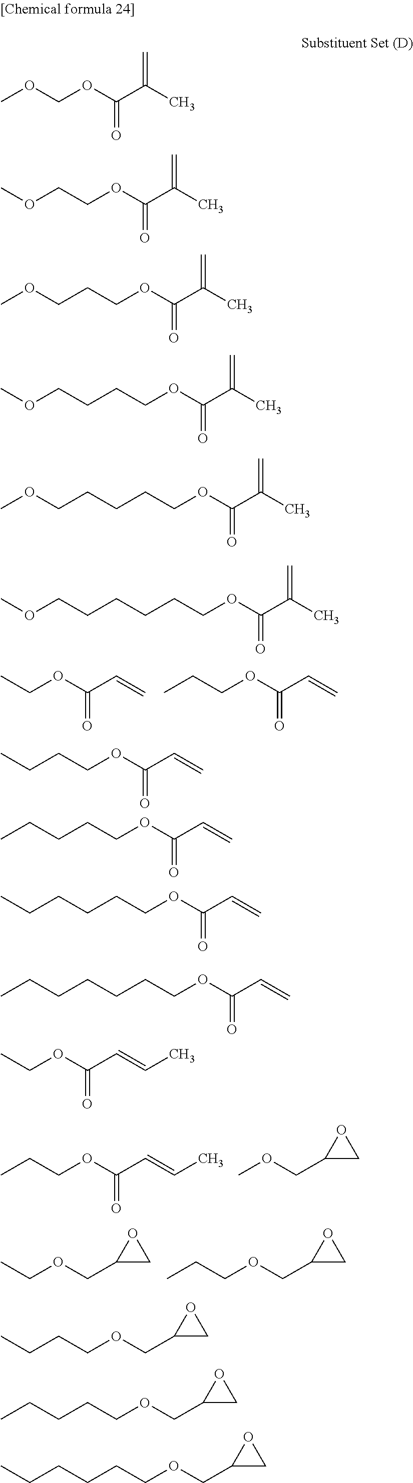

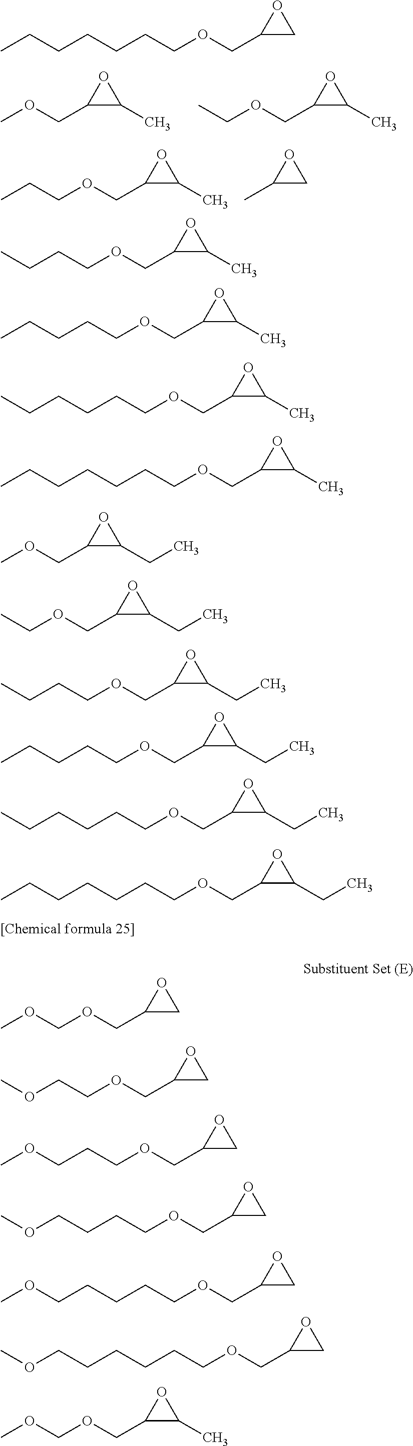

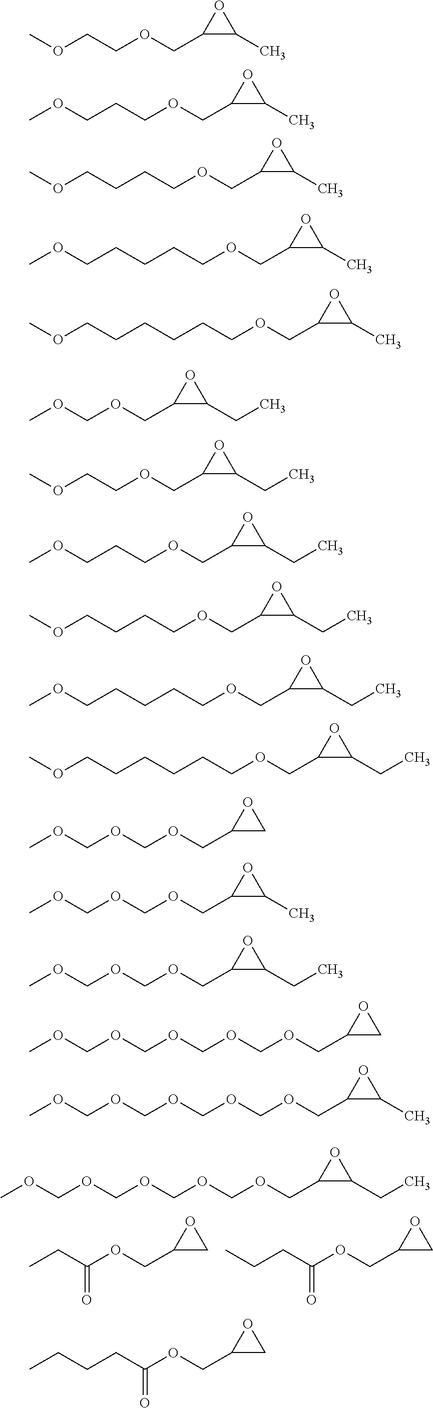

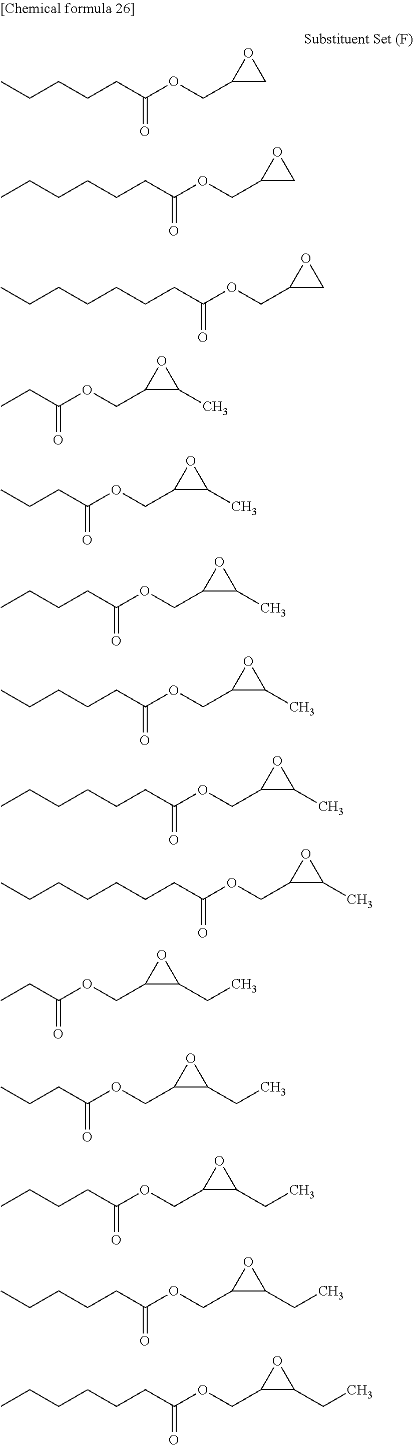

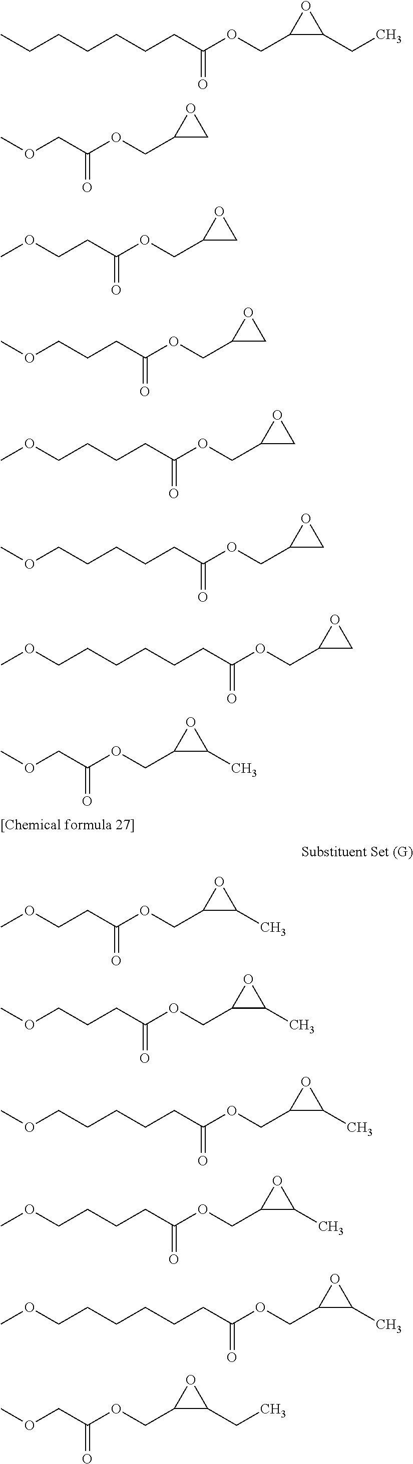

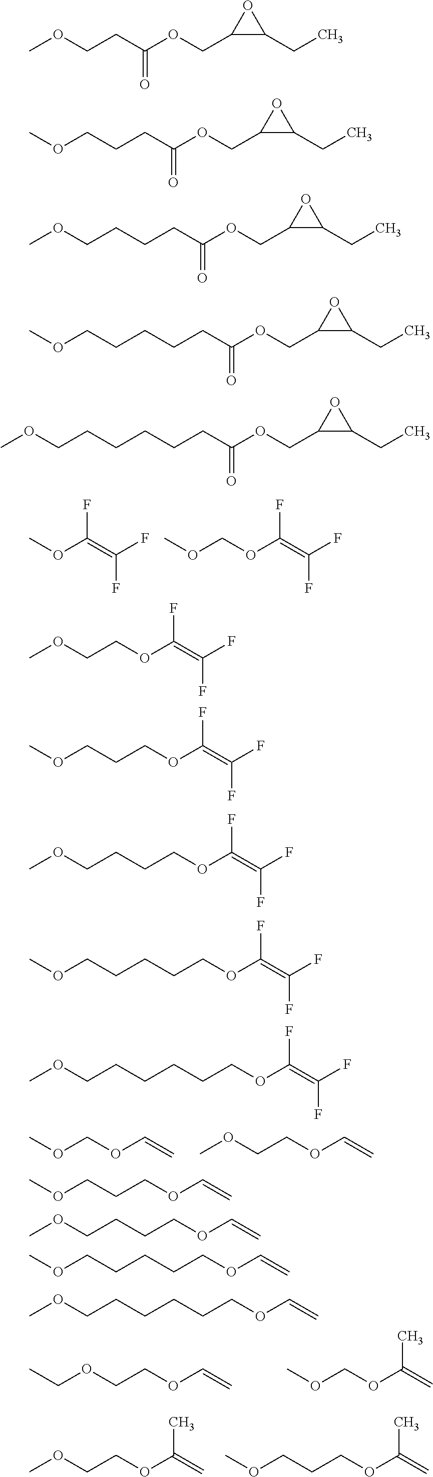

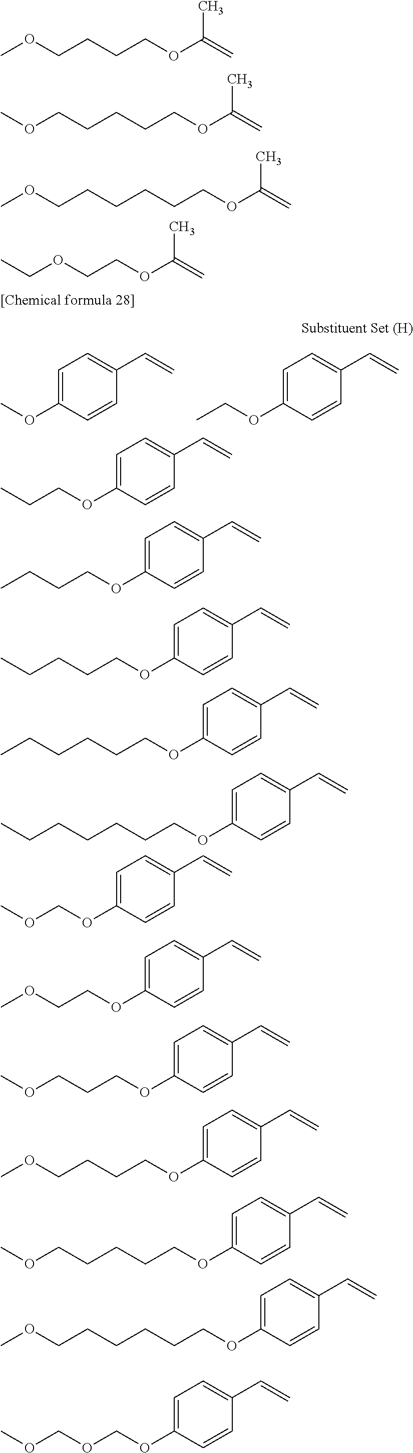

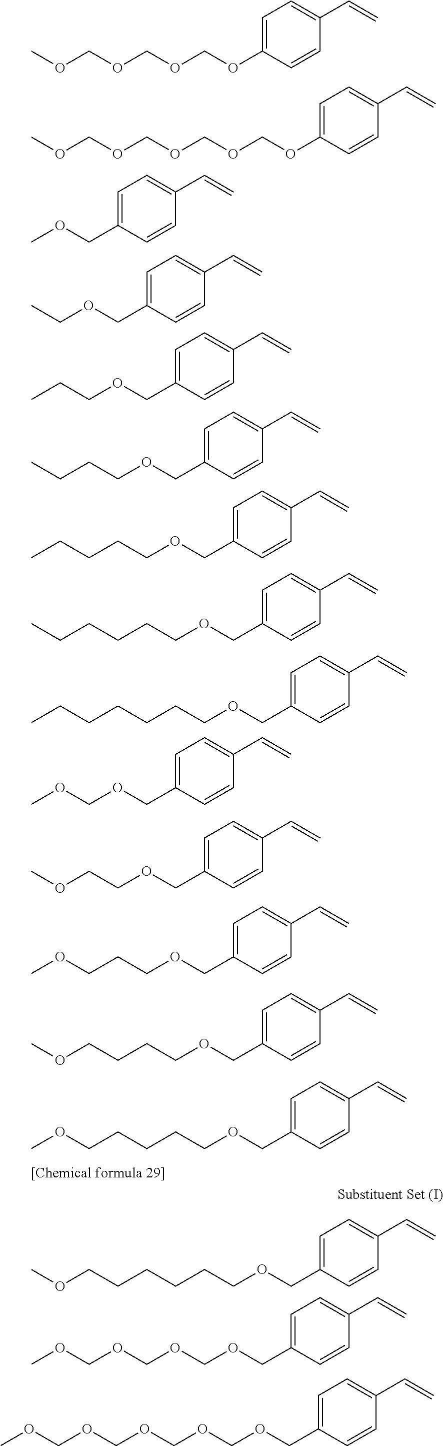

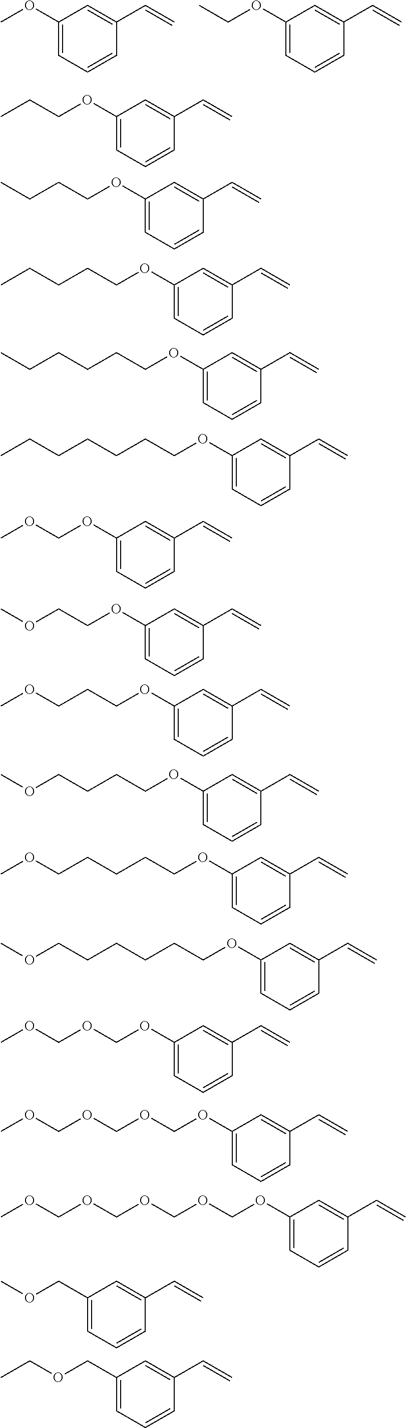

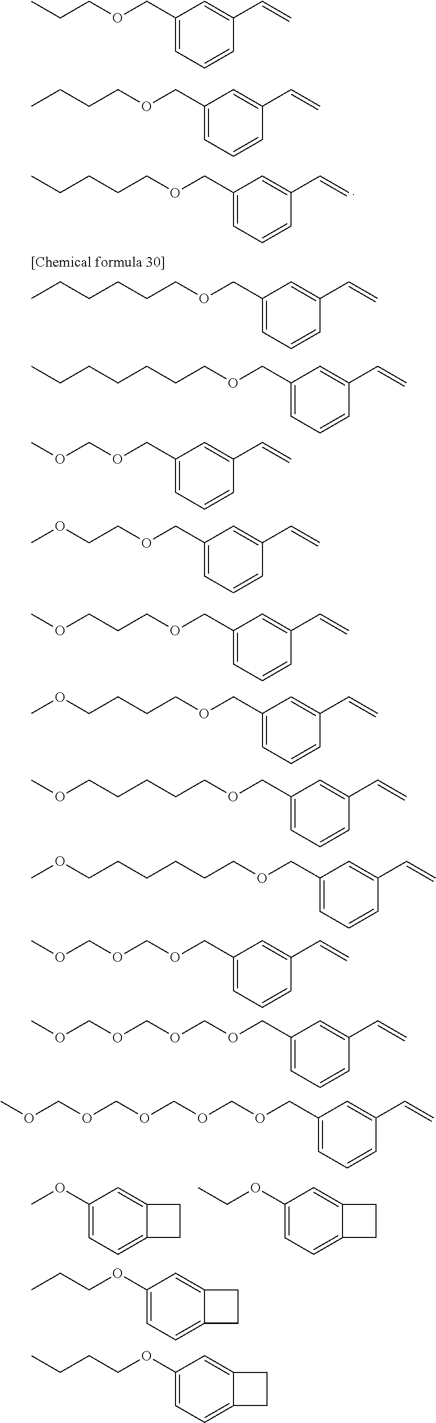

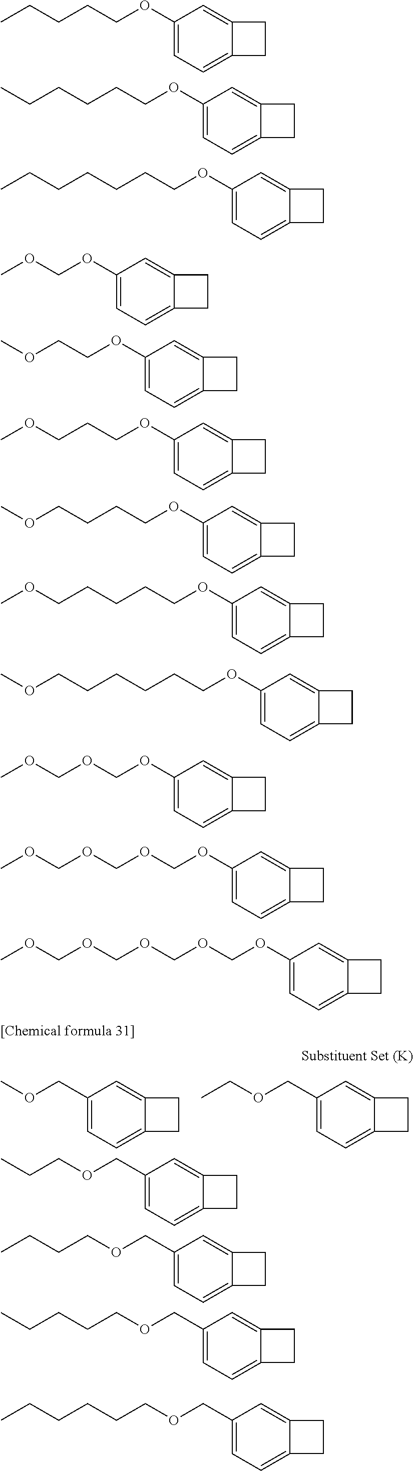

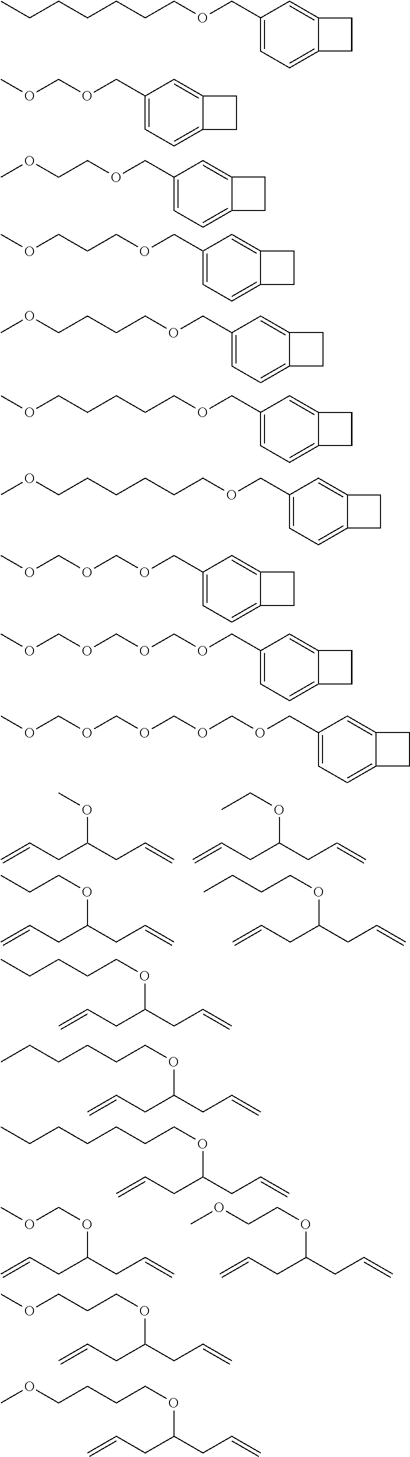

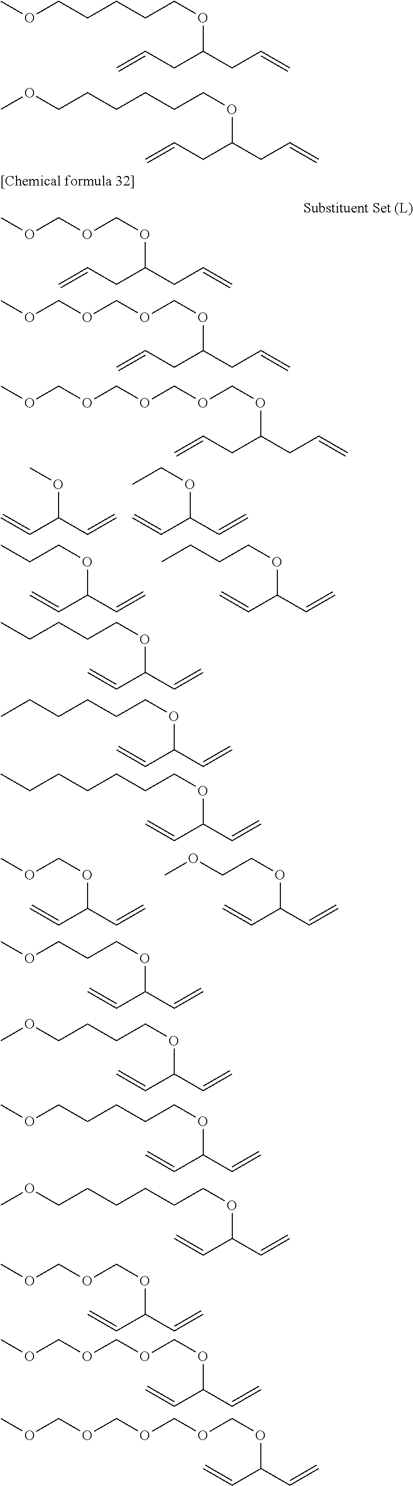

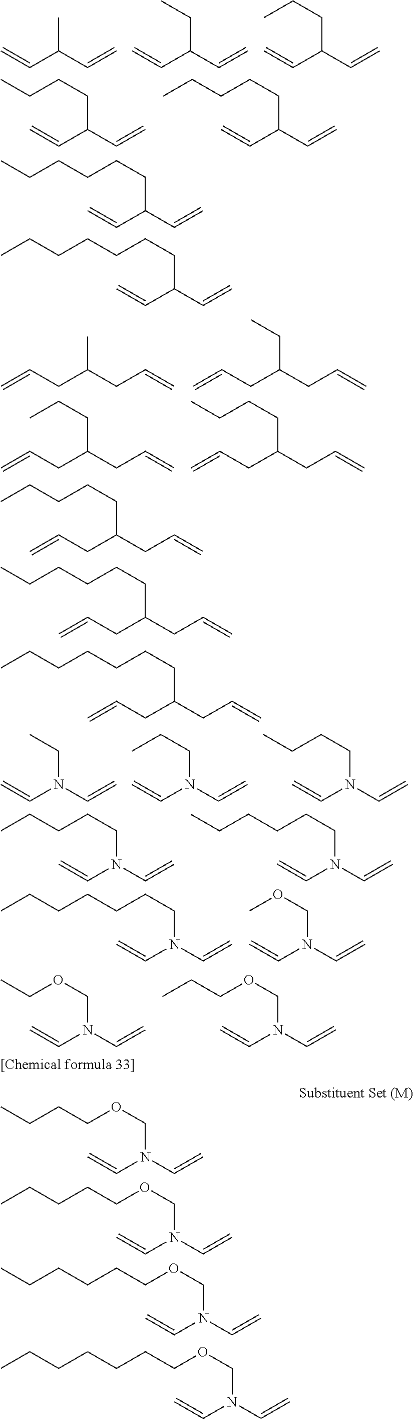

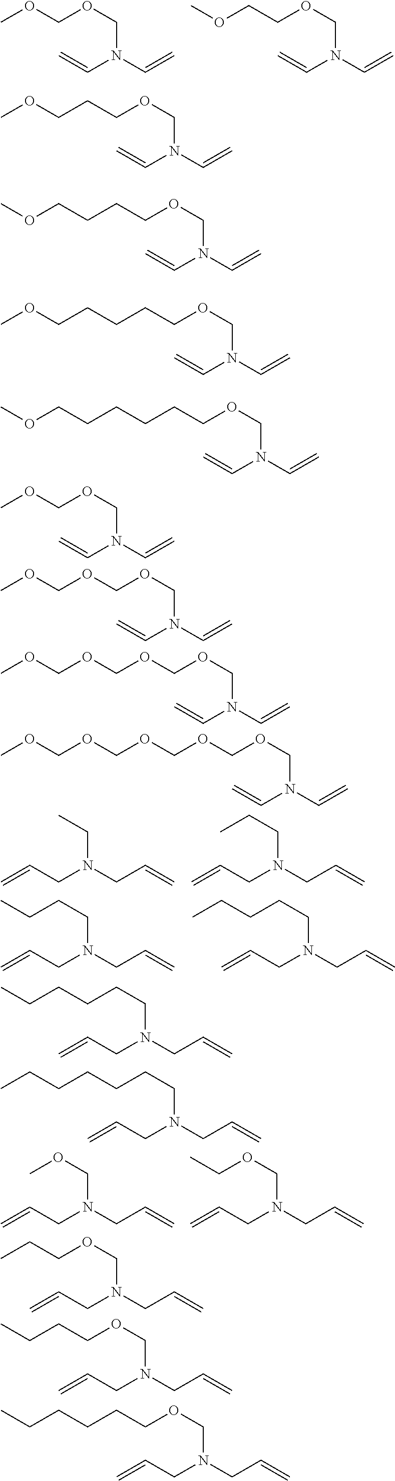

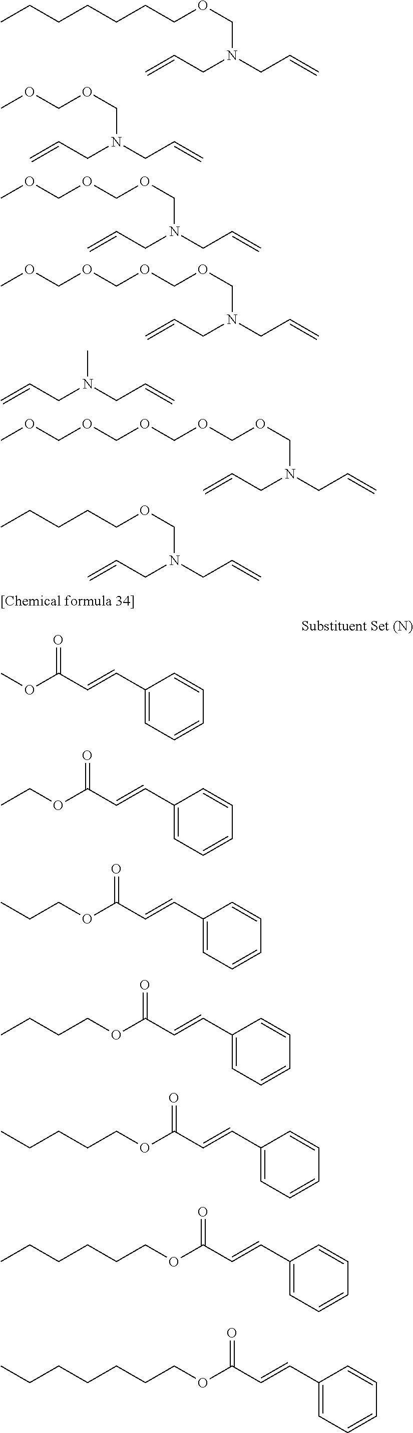

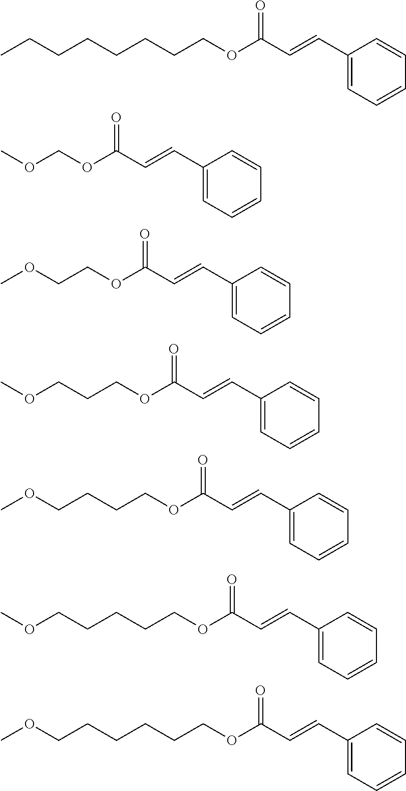

The charge transport polymer or oligomer preferably has the polymerizable substituent at a molecular chain terminal. In such cases, the charge transport polymer or oligomer has a structural unit containing the polymerizable substituent as a terminal structural unit. Specific examples include structural units (1d) having one of the groups shown above in the substituent sets (A) to (N).

In those cases where the charge transport polymer or oligomer has a structural unit containing the polymerizable substituent as a terminal structural unit, from the viewpoint of the curability of the charge transport polymer or oligomer, the proportion of that structural unit across all of the terminals is preferably at least 5%, more preferably at least 10%, and even more preferably at least 15%, relative to the total number of terminals. From the viewpoint of improving the characteristics of the organic electronic element, the proportion of that structural unit across all of the terminals is preferably not more than 75%, more preferably not more than 70%, and even more preferably 65% or less, relative to the total number of terminals.

The charge transport polymer or oligomer may be a homopolymer having only one type of structural unit, or may be a copolymer having two or more types of structural unit. In those cases where the charge transport polymer or oligomer is a copolymer, the copolymer may be an alternating, random, block or graft copolymer, or a copolymer having an intermediate type structure, such as a random copolymer having block-like properties.

The charge transport polymer or oligomer has at least a divalent structural unit having charge transport properties and a monovalent structural unit having a condensed polycyclic aromatic hydrocarbon moiety, and may also have a branch origin structural unit and/or a monovalent structural unit having another terminal moiety.

From the viewpoint of obtaining satisfactory charge transport properties, the proportion of the total number of divalent structural units having charge transport properties (such as the structural units (1a) to (84a)) relative to the total number of all the structural units in the charge transport polymer or oligomer is preferably at least 10%, more preferably at least 20%, and even more preferably 30% or greater. From the viewpoint of achieving superior charge injection properties and charge transport properties, this proportion of the total number of divalent structural units having charge transport properties (such as the structural units (1a) to (84a)) is preferably high. From the viewpoint of enhancing the durability while imparting favorable charge transport properties, the proportion is preferably not more than 95%, more preferably not more than 90%, and even more preferably 85% or less.

The “proportion of a structural unit” can be determined from the blend ratio (molar ratio) of the monomer corresponding with that structural unit used in the synthesis of the charge transport polymer or oligomer.

In those cases where the charge transport polymer or oligomer has a branch origin structural unit, from the viewpoint of ensuring satisfactory covering of the unevenness caused by the anode, the proportion of the total number of branch origin structural units (such as the structural units (1b) to (11b)) relative to the total number of all the structural units in the charge transport polymer or oligomer is preferably at least 1%, more preferably at least 5%, and even more preferably 10% or greater. From the viewpoint of ensuring favorable synthesis of the charge transport polymer or oligomer, this proportion of the total number of branch origin structural units (such as the structural units (1b) to (11b)) is preferably not more than 50%, more preferably not more than 40%, and even more preferably 30% or less.

From the viewpoint of improving the characteristics of the organic electronic element, the proportion of the total number of structural units having a condensed polycyclic aromatic hydrocarbon moiety (such as the structural unit (1c)) relative to the total number of all the structural units in the charge transport polymer or oligomer is preferably at least 5%, more preferably at least 10%, and even more preferably 15% or greater. From the viewpoint of preventing any deterioration in the hole transport properties, this proportion of the total number of structural units having a condensed polycyclic aromatic hydrocarbon moiety (such as the structural unit (1c)) is preferably not more than 95%, more preferably not more than 90%, and even more preferably 85% or less.

In those cases where the charge transport polymer or oligomer has a structural unit having another terminal moiety, from the viewpoint of improving the solubility and the film formability and the like, the proportion of the total number of structural units having another terminal moiety (such as the structural unit (1d)) relative to the total number of all the structural units in the charge transport polymer or oligomer is preferably at least 5%, more preferably at least 10%, and even more preferably 15% or greater. From the viewpoint of preventing any deterioration in the hole transport properties, this proportion of the total number of structural units having another terminal moiety (such as the structural unit (1d)) is preferably not more than 95%, more preferably not more than 90%, and even more preferably 85% or less.

From the viewpoint of achieving superior hole injection properties and hole transport properties and the like, the charge transport polymer or oligomer is preferably a compound in which a structural unit having an aromatic amine structure and/or a structural unit having a carbazole structure are contained as the main structural unit (the main backbone). Further, from the viewpoint of facilitating multilayering, the charge transport polymer or oligomer is preferably a compound having two or more polymerizable substituents. From the viewpoint of offering superior curability, the polymerizable substituents are preferably groups having a cyclic ether structure, or groups having a carbon-carbon multiple bond or the like.

The number average molecular weight of the charge transport polymer or oligomer may be adjusted appropriately with due consideration of the solubility in solvents and the film formability and the like. From the viewpoint of ensuring superior charge transport properties, the number average molecular weight is preferably at least 500, more preferably at least 1,000, and even more preferably at 2,000 or greater. From the viewpoints of maintaining favorable solubility in solvents and facilitating the preparation of compositions, the number average molecular weight is preferably not more than 1,000,000, more preferably not more than 100,000, and even more preferably 50,000 or less. The number average molecular weight refers to the standard polystyrene-equivalent number average molecular weight measured by gel permeation chromatography (GPC).

The weight average molecular weight of the charge transport polymer or oligomer may be adjusted appropriately with due consideration of the solubility in solvents and the film formability and the like. From the viewpoint of ensuring superior charge transport properties, the weight average molecular weight is preferably at least 1,000, more preferably at least 5,000, and even more preferably 10,000 or greater. From the viewpoints of maintaining favorable solubility in solvents and facilitating the preparation of compositions, the weight average molecular weight is preferably not more than 1,000,000, more preferably not more than 700,000, and even more preferably 400,000 or less. The weight average molecular weight refers to the standard polystyrene-equivalent weight average molecular weight measured by gel permeation chromatography (GPC).

### (Production Method)

The charge transport polymer or oligomer can be produced by various synthesis methods, and there are no particular limitations. The condensed polycyclic aromatic hydrocarbon moiety may be introduced into a conventional charge transport polymer or oligomer. Examples of the synthesis method include conventional coupling reactions such as the Suzuki coupling, Negishi coupling, Sonogashira coupling, Stille coupling and Buchwald-Hartwig coupling reactions. The Suzuki coupling is a reaction in which a cross-coupling reaction is initiated between an aromatic boronic acid derivative and an aromatic halogen compound using a Pd catalyst. By using a Suzuki coupling, the charge transport polymer or oligomer can be produced easily by bonding together the desired aromatic rings.

In the coupling reaction, a Pd(0) compound, Pd(II) compound, or Ni compound or the like is used as a catalyst. Further, a catalyst species generated by mixing a precursor such as tris(dibenzylideneacetone)dipalladium(0) or palladium(II) acetate with a phosphine ligand can also be used.

In the synthesis of the charge transport polymer or oligomer, monomers corresponding with the divalent structural units, trivalent or higher structural units and monovalent structural units described above can be used. Examples of the monomers are shown below.

### <Monomer A>

R-A-R [Chemical formula 34a]

### <Monomer B>

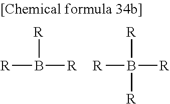

### <Monomer C>

R—C [Chemical formula 34c]

### <Monomer D>

R-D [Chemical formula 34d]

In the above formulas, A represents a divalent structural unit, C represents a terminal structural unit having a “condensed polycyclic aromatic hydrocarbon moiety”, D represents a terminal structural unit having “another terminal moiety”, and B represents a trivalent or tetravalent structural unit. R represents a functional group that can form a bond with another group, and it is preferable that each R independently represents a group selected from the group consisting of a boronic acid group, a boronate ester group and halogen groups.

From the viewpoint of achieving superior charge transport properties, the amount of the charge transport polymer or oligomer within the organic electronic material, relative to the total mass of the organic electronic material, is preferably at least 50% by mass, more preferably at least 55% by mass, and even more preferably 60% by mass or greater. There are no particular limitations on the upper limit for the amount of the charge transport polymer or oligomer, and the amount may be 100% by mass, but if consideration is given to including the types of additives described below in the organic electronic material, then the amount is typically not more than 99.5% by mass.

### [Additives]

In the present embodiment, the organic electronic material contains at least the charge transport polymer or oligomer. In addition to the charge transport polymer or oligomer, the organic electronic material may also contain various conventional additives typically used in the technical field as organic electronic material additives. For example, in order to adjust the charge transport properties, the organic material may also contain electron-accepting compounds that can function as electron acceptors relative to the charge transport polymer or oligomer, electron-donating compounds that can function as electron donors, radical polymerization initiators and cationic polymerization initiators that can function as polymerization initiators, and the like. An organic electronic material that contains the hole transport polymer or oligomer and also contains an electron-accepting compound is preferred in terms of making it easier to achieve excellent hole transport properties.

### (Electron-Accepting Compounds)

Specific examples of compounds that can be used as electron-accepting compounds include both inorganic substances and organic substances. For example, the electron-accepting compounds disclosed in JP 2003-031365 A and JP 2006-233162 A, and the super Broensted acid compounds and derivatives disclosed in JP 3957635 B and JP 2012-72310 A may be used. Further, onium salts containing at least one type of cation selected from the cations below and at least one type of anion from the anions below may also be used. In those cases where the charge transport polymer or oligomer has a polymerizable substituent, an onium salt can also be used favorably from the viewpoint of improving the curability of the charge transport polymer or oligomer.

### (Cations)

Examples of the cation include H⁺, a carbenium ion, ammonium ion, anilinium ion, pyridinium ion, imidazolium ion, pyrrolidinium ion, quinolinium ion, imonium ion, aminium ion, oxonium ion, pyrylium ion, chromenylium ion, xanthylium ion, iodonium ion, sulfonium ion, phosphonium ion, tropylium ion and cations having a transition metal, and of these, a carbenium ion, ammonium ion, anilinium ion, aminium ion, iodonium ion, sulfonium ion, or tropylium ion or the like is preferred. From the viewpoint of achieving a favorable combination of charge transport properties and storage stability, an ammonium ion, anilinium ion, iodonium ion, or sulfonium ion or the like is more preferable, and an iodonium ion is even more preferred.

### (Anions)

Examples of the anion include halogen ions such as F⁻, Cl⁻, Br⁻ and I⁻; OH⁻; ClO₄⁻; sulfonate ions such as FSO₃⁻, ClSO₃⁻, CH₃SO₃⁻, C₆H₅SO₃⁻ and CF₃SO₃⁻; sulfate ions such as HSO₄⁻ and SO₄²⁻; carbonate ions such as HCO₃⁻ and CO₃²⁻; phosphate ions such as H₂PO₄⁻, HPO₄²⁻ and PO₄³⁻; fluorophosphate ions such as PF₆⁻ and PF₅OH⁻; fluoroalkyl fluorophosphate ions such as [(CF₃CF₂)₃PF₃]⁻, [(CF₃CF₂CF₂)₃PF₃]⁻, [((CF₃)₂CF)₃PF₃]⁻, [((CF₃)₂CF)₂PF₄]⁻, [((CF₃)₂CFCF₂)₃PF₃]⁻ and [((CF₃)₂CFCF₂)₂PF₄]⁻; fluoroalkane sulfonyl methide and imide ions such as (CF₃SO₂)₃C⁻ and (CF₃SO₂)₂N⁻; borate ions such as BF₄⁻, B(C₆H₅)₄⁻ and B(C₆H₄CF₃)₄⁻; fluoroantimonate ions such as SbF₆⁻ and SbF₅OH⁻; fluoroarsenate ions such as AsF₆⁻ and AsF₅OH⁻; AlCl₄⁻ and BiF₆⁻. Among these, fluorophosphate ions such as PF₆⁻ and PF₅OH⁻; fluoroalkyl fluorophosphate ions such as [((CF₃CF₂)₃PF₃]⁻, [(CF₃CF₂CF₂)₃PF₃]⁻, [((CF₃)₂CF)₃PF₃]⁻, [((CF₃)₂CF)₂PF₄]⁻, [((CF₃)₂CFCF₂)₃PF₃]⁻ and [((CF₃)₂CFCF₂)₂PF₄]⁻; fluoroalkane sulfonyl methide and imide ions such as (CF₃SO₂)₃C⁻ and (CF₃SO₂)₂N⁻; borate ions such as BF₄⁻, B(C₆H₅)₄⁻ and B(C₆H₄CF₃)₄⁻; and fluoroantimonate ions such as SbF₆⁻ and SbF₅OH⁻ are preferred, and borate ions are particularly preferred.

An onium salt having an anion containing an electron-withdrawing substituent is preferably used as the electron-accepting compound. Specific examples include the compounds shown below.

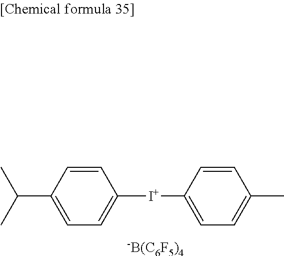 [SMILES: "-B(C6F5)4" ; Cc1ccc([I+]c2ccc(C(C)C)cc2)cc1]

In those cases where an electron-accepting compound is used, from the viewpoint of improving the charge transport properties of the organic electronic material, the amount of the electron-accepting compound relative to the total mass of the organic electronic material is preferably at least 0.01% by mass, more preferably at least 0.1% by mass, and even more preferably 0.5% by mass or greater. From the viewpoint of maintaining favorable film formability, the amount is preferably not more than 50% by mass, more preferably not more than 30% by mass, and even more preferably 20% by mass or less, relative to the total mass of the organic electronic material.

### <Ink Composition>

The ink composition that represents an embodiment of the present invention contains the organic electronic material of the embodiment described above and a solvent. Any solvent that enables formation of a coating layer using the organic electronic material may be used as the solvent. A solvent that can dissolve the organic electronic material is preferably used. By using the ink composition, an organic layer can be formed easily via a simple coating method.

### [Solvent]

Examples of the solvent include water and organic solvents. Examples of the organic solvent include alcohols such as methanol, ethanol and isopropyl alcohol; alkanes such as pentane, hexane and octane; cyclic alkanes such as cyclohexane; aromatic hydrocarbons such as benzene, toluene, xylene, mesitylene, tetralin and diphenylmethane; aliphatic ethers such as ethylene glycol dimethyl ether, ethylene glycol diethyl ether and propylene glycol-1-monomethyl ether acetate; aromatic ethers such as 1,2-dimethoxybenzene, 1,3-dimethoxybenzene, anisole, phenetole, 2-methoxytoluene, 3-methoxytoluene, 4-methoxytoluene, 2,3-dimethylanisole and 2,4-dimethylanisole; aliphatic esters such as ethyl acetate, n-butyl acetate, ethyl lactate and n-butyl lactate; aromatic esters such as phenyl acetate, phenyl propionate, methyl benzoate, ethyl benzoate, propyl benzoate and n-butyl benzoate; amide-based solvents such as N,N-dimethylformamide and N,N-dimethylacetamide; as well as dimethyl sulfoxide, tetrahydrofuran, acetone, chloroform and methylene chloride and the like. The solvent preferably includes at least one type of solvent selected from the group consisting of aromatic hydrocarbons, aliphatic esters, aromatic esters, aliphatic ethers and aromatic ethers.

The amount of the solvent in the ink composition can be determined with due consideration of the use of the composition in various coating methods. For example, the amount of the solvent is preferably an amount that yields a ratio of the charge transport polymer or oligomer relative to the solvent that is at least 0.1% by mass, more preferably at least 0.2% by mass, and even more preferably 0.5% by mass or greater. The amount of the solvent is preferably an amount that yields a ratio of the charge transport polymer or oligomer relative to the solvent that is not more than 10% by mass, more preferably not more than 5% by mass, and even more preferably 3% by mass or less.

### (Other Additives)

The ink composition may also contain various other additives. Specific examples of these various additives include polymerization inhibitors, stabilizers, thickeners, gelling agents, flame retardants, antioxidants, reduction inhibitors, oxidizing agents, reducing agents, surface modifiers, emulsifiers, antifoaming agents, dispersants and surfactants.

### <Organic Layer>

The organic layer that represents one embodiment of the present invention is a layer formed using the organic electronic material or the ink composition of an embodiment described above. The organic layer is a layer that contains the organic electronic material. The organic electronic material may be contained in the organic layer as the organic electronic material itself, or as a derivative derived from the organic electronic material, such as a polymerization product, reaction product or degradation product. The organic layer can be formed favorably from the ink composition using a coating method. Examples of the coating method used for applying the ink composition include conventional methods such as spin coating methods, casting methods, dipping methods, plate-based printing methods such as relief printing, intaglio printing, offset printing, lithographic printing, relief reversal offset printing, screen printing and gravure printing, and plateless printing methods such as inkjet methods. When the organic layer is formed by a coating method, the coating layer obtained following application of the ink composition may be dried using a hotplate or an oven to remove the solvent.

When the charge transport polymer or oligomer has a polymerizable substituent, because the coating layer can be cured by polymerization, multilayering can be achieved easily by using a coating method to add another organic layer. A method employing light irradiation or heating or the like is generally used as the trigger to initiate polymerization of the charge transport polymer or oligomer. Although there are no particular limitations, from the viewpoint of the convenience of the process, a method that employs heating is preferred.

When a method that employs light irradiation is used, a light source such as a low-pressure mercury lamp, medium-pressure mercury lamp, high-pressure mercury lamp, ultra-high-pressure mercury lamp, metal halide lamp, xenon lamp, fluorescent lamp, light-emitting diode or sunlight may be used. The wavelength of the irradiated light is typically from 200 to 800 nm.

For the heating, a heating device such as a hotplate or an oven can be used. The heating temperature and heating time may be adjusted to levels that ensure the polymerization reaction proceeds satisfactorily. Although there are no particular limitations, the heating temperature is preferably not more than 300° C., more preferably not more than 250° C., and even more preferably 200° C. or lower. By using a temperature within the above range, a wide variety of substrates can be used. Further, from the viewpoint of increasing the polymerization rate of the coating layer, the heating temperature is preferably at least 40° C., more preferably at least 50° C., and even more preferably 60° C. or higher. From the viewpoint of raising the productivity, the heating time is preferably not longer than 2 hours, more preferably not longer than 1 hour, and even more preferably 30 minutes or shorter. Further, from the viewpoint of ensuring that the polymerization proceeds to completion, the heating time is preferably at least 1 minute, more preferably at least 3 minutes, and even more preferably 5 minutes or longer.

From the viewpoint of improving the efficiency of hole transport, the thickness of the organic layer is preferably at least 0.1 nm, more preferably at least 1 nm, and even more preferably 3 nm or greater. Further, from the viewpoint of reducing the electrical resistance of the organic layer, the thickness is preferably not more than 300 nm, more preferably not more than 200 nm, and even more preferably 100 nm or less.

### <Organic Electronic Element>

The organic electronic element that represents one embodiment of the present invention has at least an organic layer of the embodiment described above. Examples of the organic electronic element include an organic electroluminescent (organic EL) element, an organic thin-film solar cell, and an organic light-emitting transistor. The organic electronic element preferably has at least a structure in which an organic layer is disposed between a pair of electrodes.

### <Organic EL Element>

A specific embodiment of an organic EL element is described below as one example of the organic electronic element. The organic EL element of this embodiment of the present invention has an organic layer formed using the organic electronic material. An organic EL element typically has a substrate, at least one pair of an anode and a cathode, and a light-emitting layer, and if necessary, may also have one or more other layers such as a hole injection layer, electron injection layer, hole transport layer, and electron transport layer. Embodiments of the organic EL element may have organic layers as the light-emitting layer and as other layers. A preferred embodiment of the organic EL element has the organic layer as at least one of a hole injection layer and a hole transport layer.

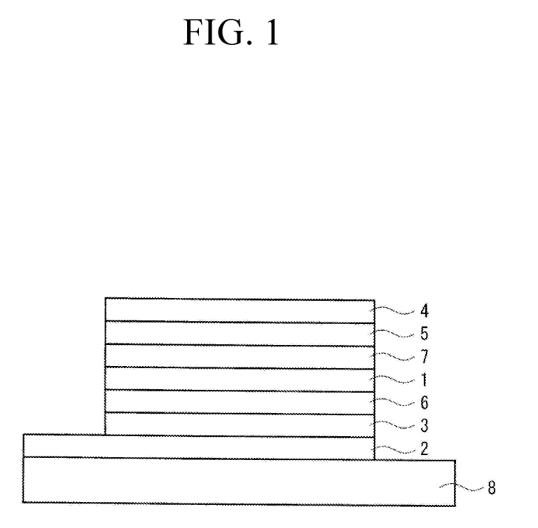

FIG. 1 is a cross-sectional schematic view illustrating one embodiment of the organic EL element. FIG. 1 illustrates the structure of an organic EL element having multiple organic layers that form a light-emitting layer 1 and a plurality of other layers. In the FIGURE, 2 indicates an anode, 3 indicates a hole injection layer, 4 indicates a cathode, and 5 indicates an electron injection layer. Further, 6 indicates a hole transport layer, 7 indicates an electron transport layer, and 8 indicates a substrate. Each layer is described below in further detail.

### (Light-Emitting Layer)

The material used for the light-emitting layer may be a low-molecular weight compound, a polymer or oligomer, or a dendrimer or the like. Examples of low-molecular weight compounds that use fluorescence emission include perylene, coumarin, rubrene, quinacridone, color laser dyes (such as rhodamine and DCM1), aluminum complexes (such as tris(8-hydroxyquinolinato)aluminum(III) (Alq₃)), stilbene, and derivatives of these compounds. Examples of polymers or oligomers using fluorescence emission that can be used favorably include polyfluorene, polyphenylene, polyphenylenevinylene (PPV), polyvinylcarbazole (PVK), fluorene-benzothiadiazole copolymers, fluorene-triphenylamine copolymers, and derivatives and mixtures of these compounds.

On the other hand, in recent years, in order to further improve the efficiency of organic EL elements, phosphorescent organic EL elements are also being actively developed. In a phosphorescent organic EL element, not only singlet state energy, but also triplet state energy can be used, and therefore the internal quantum yield can, in principle, be increased to 100%. In a phosphorescent organic EL element, a metal complex-based phosphorescent material containing a heavy metal such as platinum or iridium is used as a phosphorescence-emitting dopant for doping a host material, thus enabling the extraction of a phosphorescence emission (see M. A. Baldo et al., Nature, vol. 395, p. 151 (1998), M. A. Baldo et al., Applied Physics Letters, vol. 75, p. 4 (1999), M. A. Baldo et al., Nature, vol. 403, p. 750 (2000)).

In the organic EL element that represents an embodiment of the present invention, a phosphorescent material is preferably used for the light-emitting layer in order to increase the element efficiency. Examples of materials that can be used favorably as the phosphorescent material include metal complexes and the like containing Ir or Pt or the like as a central metal. Specific examples of Ir complexes include FIr(pic) {iridium(III) bis[(4,6-difluorophenyl)-pyridinato-N,C²]picolinate} which emits blue light, Ir(ppy)₃ {fac-tris(2-phenylpyridine)iridium} which emits green light (see M. A. Baldo et al., Nature, vol. 403, p. 750 (2000)), and (btp)₂Ir(acac) {bis[2-(2′-benzo[4,5-α]thienyl)pyridinato-N,C³]iridium(acetyl-acetonate)} (see Adachi et al., Appl. Phys. Lett., 78 No. 11, 2001, 1622) and Ir(piq)₃ {tris(1-phenylisoqionoline)iridium} which emit red light.

Specific examples of Pt complexes include platinum 2,3,7,8,12,13,17,18-octaethyl-21H,23H-porphyrin (PtOEP) which emits red light. The phosphorescent material can use a low-molecular weight compound or a dendrite such as an iridium core dendrimer. Further, derivatives of these compounds can also be used favorably.

Furthermore, when a phosphorescent material is incorporated in the light-emitting layer, a host material is preferably included in addition to the phosphorescent material. The host material may be a low-molecular weight compound, a polymer compound, or a dendrimer or the like.

Examples of low-molecular weight compounds that can be used include α-NPD (N,N-di(1-naphthyl)-N,N-diphenylbenzidine, CBP (4,4′-bis(carbazol-9-yl)-biphenyl), mCP (1,3-bis(9-carbazolyl)benzene), and CDBP (4,4′-bis(carbazol-9-yl)-2,2′-dimethylbiphenyl). Examples of polymer compounds that can be used include polyvinylcarbazole, polyphenylene and polyfluorene. Further, derivatives of these compounds can also be used.

The light-emitting layer may be formed by a vapor deposition method or a coating method.

Forming the light-emitting layer by a coating method enables the organic EL element to be formed more cheaply, and is consequently preferred. Formation of the light-emitting layer by a coating method can be achieved by using a conventional coating method to apply a solution containing the phosphorescent material, and if necessary a host material, to a desired substrate. Examples of the coating method include spin coating methods, casting methods, dipping methods, plate-based printing methods such as relief printing, intaglio printing, offset printing, lithographic printing, relief reversal offset printing, screen printing and gravure printing, and plateless printing methods such as inkjet methods.

### [Cathode]

The cathode material is preferably a metal or a metal alloy, such as Li, Ca, Mg, Al, In, Cs, Ba, Mg/Ag, LiF or CsF. There are no particular limitations on the formation of the cathode, and conventional methods may be employed.

### (Anode)

A metal (for example, Au) or another material having metal-like conductivity can be used as the anode. Examples of the other materials include oxides (for example, ITO: indium oxide/tin oxide) and conductive polymers (for example, polythiophene-polystyrene sulfonate mixtures (PEDOT:PSS)). There are no particular limitations on the formation of the anode, and conventional methods may be employed.

### (Other Functional Layers)

In addition to the light-emitting layer, the organic EL element preferably has at least one layer selected from the group consisting of a hole injection layer, an electron injection layer, a hole transport layer and an electron transport layer as a functional layer. In one embodiment, the organic EL element preferably includes at least one of a hole injection layer and a hole transport layer. Representative functional layers are described below.

### (Hole Injection Layer, Hole Transport Layer)

The organic EL element preferably has an organic layer formed using the organic electronic material of the embodiment described above as at least one of a hole injection layer and a hole transport layer. In one embodiment, the organic EL element preferably has an organic layer formed using the organic electronic material of the embodiment described above as a hole transport layer. In this embodiment, the hole transport layer can be formed easily using an ink composition containing the organic electronic material. In those cases where the organic EL element also has a hole injection layer, there are no particular limitations on the hole injection layer, which may be formed using a conventional material that is known within the technical field. The organic electronic material of the embodiment described above may also be used for forming the hole injection layer.

In another embodiment, the organic EL element preferably has an organic layer formed using the organic electronic material of the embodiment described above as a hole injection layer. In this embodiment, the hole injection layer can be formed easily using an ink composition containing the organic electronic material. In those cases where the organic EL element also has a hole transport layer, there are no particular limitations on the hole transport layer, which may be formed using a conventional material that is known within the technical field. The organic electronic material of the embodiment described above may also be used for forming the hole transport layer.

In one embodiment, an ink composition is applied to form a coating layer, the coating layer is then cured to form a hole injection layer, and subsequently, an ink composition is applied to the formed hole injection layer to form a coating layer, which is then dried or cured, thus enabling stacking of a hole injection layer and a hole transport layer to be performed with ease.

### (Electron Transport Layer, Electron Injection Layer)

Formation of an electron transport layer and an electron injection layer can be achieved using methods conventionally known in the technical field. Examples of materials that can be used for forming the electron transport layer and/or the electron injection layer include phenanthroline derivatives (such as 2,9-dimethyl-4,7-diphenyl-1,10-phenanthroline (BCP)), bipyridine derivatives, nitro-substituted fluorene derivatives, diphenylquinone derivatives, thiopyran dioxide derivatives, heterocyclic tetracarboxylic acid anhydrides such as naphthaleneperylene, carbodiimides, fluorenylidenemethane derivatives, anthraquinodimethane and anthrone derivatives, oxadiazole derivatives (such as 2-(4-biphenylyl)-5-(4-tert-butylphenyl-1,3,4-oxadiazole (PBD)), benzimidazole derivatives (such as 1,3,5-tris(1-phenyl-1H-benzimidazol-2-yl)benzene) (TPBi)), and aluminum complexes (such as tris(8-hydroxyquinolinato)aluminum(III) (Alq₃) and bis(2-methyl-8-quninolinato)-4-phenylphenolate aluminum(III) (BAlq)). Moreover, thiadiazole derivatives in which the oxygen atom in the oxadiazole ring of the oxadiazole derivatives mentioned above has been substituted with a sulfur atom, and quinoxaline derivatives having a quinoxaline ring that is well known as an electron-withdrawing group can also be used.

### (Substrate)

Although there are no particular limitations on the substrates that can be used in the organic EL element, substrates of glass and resin films and the like are preferred. In one embodiment, a substrate having flexibility known in the technical field as a flexible substrate is preferably used. Examples of the flexible substrate include substrates containing at least one material selected from the group consisting of thin-film glass, aluminum foil and resin films. Further, the substrate is preferably transparent. In that regard, a glass substrate, quartz substrate, or a substrate containing a light-transmitting resin film or the like is preferred. Among these options, using a light-transmitting resin film as the substrate is particularly desirable, as not only is the transparency excellent, but the organic EL element can also be easily imparted with flexibility.

Examples of the resin film include polyethylene terephthalate (PET), polyethylene naphthalate (PEN), polyethersulfone (PES), polyetherimide, polyetheretherketone, polyphenylene sulfide, polyarylate, polyimide, polycarbonate (PC), cellulose triacetate (TAC) and cellulose acetate propionate (CAP).

Furthermore, in those cases when a resin film is used, an inorganic substance such as silicon oxide or silicon nitride may be coated onto the resin film to inhibit the transmission of water vapor and oxygen and the like. Further, a single resin film may be used alone, or a plurality of resin films may be combined to form a multilayer substrate.

### (Encapsulation)

The organic EL element may be encapsulated to reduce the effects of the outside atmosphere and extend the life of the element. Materials that can be used for the encapsulation include glass, plastic films such as epoxy resins, acrylic resins, PET and PEN, and inorganic substances such as silicon oxide and silicon nitride.

There are no particular limitations on the encapsulation method. Examples of methods that can be used include methods in which the encapsulation material is formed directly on the organic EL element by vacuum deposition, sputtering, or a coating method or the like, and methods in which an encapsulation material such as glass or a plastic film is bonded to the organic EL element with an adhesive.

### (Emission Color)

Although there are no particular limitations on the color of the light emission from the organic EL element, white light-emitting elements can be used for various lighting fixtures, including domestic lighting, in-vehicle lighting, watches and liquid crystal backlights, and are consequently preferred.

For a white light-emitting element, generating white light emission from a single material is currently impossible. Accordingly, a white light emission is obtained by simultaneously emitting a plurality of colors using a plurality of light-emitting materials, and then mixing the emitted colors to obtain a white light emission. There are no particular limitations on the combination of the plurality of emission colors, and examples include combinations that include three maximum emission wavelengths for blue, green and red, and combinations that include two maximum emission wavelengths for blue and yellow, or for yellowish green and orange or the like. Control of the emission color can be achieved by appropriate adjustment of the types and amounts of the phosphorescent materials.

### <Display Element, Illumination Device, Display Device>

A display element that represents one embodiment of the present invention contains the organic EL element of the embodiment described above. For example, by using the above organic EL element as the element corresponding with each color pixel of red, green and blue (RGB), a color display element can be obtained. Image formation may employ a simple matrix in which organic EL elements arrayed in a panel are driven directly by an electrode arranged in a matrix, or an active matrix in which a thin-film transistor is positioned on, and drives, each element. The former has a simpler structure, but there is a limit to the number of vertical pixels, and therefore these types of displays are typically used for displaying text or the like. The latter has a lower drive voltage, requires less current and yields a bright high-quality image, and is therefore preferably used for high-quality displays.

Further, the illumination device that represents one embodiment of the present invention contains the organic EL element of the embodiment described above. Moreover, the display device that represents another embodiment of the present invention contains the above illumination device and a liquid crystal element as a display unit. One example is a display device that uses the illumination device as a backlight (white light-emitting source) and uses a liquid crystal element as the display unit, namely a liquid crystal display device. This configuration is merely a conventional liquid crystal display device in which only the backlight has been replaced with the above illumination device, with the liquid crystal element portion employing conventional technology.

### EXAMPLES

The present invention is described below in further detail using a series of examples, but the present invention is not limited by the following examples.

### <Preparation of Pd Catalyst>

In a glove box under a nitrogen atmosphere and at room temperature, tris(dibenzylideneacetone)dipalladium (73.2 mg, 80 μmol) was weighed into a sample tube, anisole (15 mL) was added, and the resulting mixture was agitated for 30 minutes. In a similar manner, tris(t-butyl)phosphine (129.6 mg, 640 μmol) was weighed into a sample tube, anisole (5 mL) was added, and the resulting mixture was agitated for 5 minutes. The two solutions were then mixed together and stirred for 30 minutes at room temperature to obtain a catalyst. All the solvents used were deaerated by nitrogen bubbling for at least 30 minutes prior to use.

### <Synthesis of Charge Transport Polymer 1>

A three-neck round-bottom flask was charged with a monomer A1 shown below (5.0 mmol), a monomer B1 shown below (2.0 mmol), a monomer D1 shown below (4.0 mmol) and anisole (20 mL), and the prepared Pd catalyst solution (7.5 mL) was then added. After stirring for 30 minutes, a 10% aqueous solution of tetraethylammonium hydroxide (20 mL) was added. All of the solvents were deaerated by nitrogen bubbling for at least 30 minutes prior to use. The resulting mixture was heated and refluxed for 2 hours. All the operations up to this point were conducted under a stream of nitrogen.

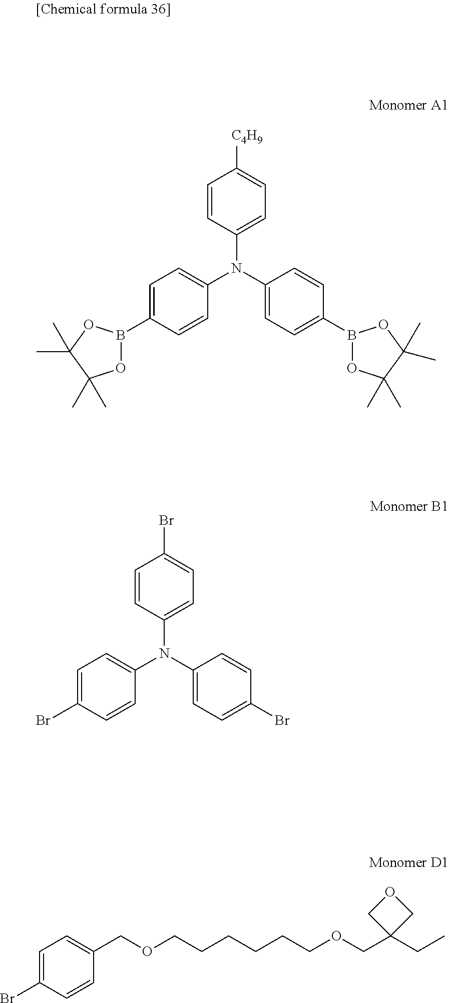

After completion of the reaction, the organic layer was washed with water, and then poured into methanol-water (9:1). The resulting precipitate was collected by filtration under reduced pressure, and then washed with methanol-water (9:1). The thus obtained precipitate was dissolved in toluene, and re-precipitated from methanol. The thus obtained precipitate was collected by filtration under reduced pressure and then dissolved in toluene, and a metal adsorbent (“Triphenylphosphine, polymer-bound on styrene-divinylbenzene copolymer”, manufactured by Strem Chemicals Inc., 200 mg per 100 mg of the precipitate) was then added to the solution and stirred overnight. Following completion of the stirring, the metal adsorbent and other insoluble matter were removed by filtration, and the filtrate was concentrated using a rotary evaporator. The concentrate was dissolved in toluene, and then re-precipitated from methanol-acetone (8:3). The thus produced precipitate was collected by filtration under reduced pressure and washed with methanol-acetone (8:3). The thus obtained precipitate was then dried under vacuum to obtain a charge transport polymer 1.

The thus obtained charge transport polymer 1 had a number average molecular of 7,800 and a weight average molecular weight of 31,000. The charge transport polymer 1 had a structural unit (1a) (derived from the monomer A1), a structural unit (2b) (derived from the monomer B1), and a structural unit (1d) having an oxetane group (derived from the monomer D1), and the proportions of those structural units were 45.5%, 18.2% and 36.4% respectively.

The number average molecular weight and the weight average molecular weight were measured by GPC (relative to polystyrene standards) using tetrahydrofuran (THF) as the eluent. The measurement conditions were as follows.

Feed pump: L-6050, manufactured by Hitachi High-Technologies Corporation

UV-Vis detector: L-3000, manufactured by Hitachi High-Technologies Corporation

Columns: Gelpack® GL-A160S/GL-A150S, manufactured by Hitachi Chemical Co., Ltd.

Eluent: THF (for HPLC, stabilizer-free), manufactured by Wako Pure Chemical Industries, Ltd.

Flow rate: 1 mL/min

Column temperature: room temperature

Molecular weight standards: standard polystyrenes

### <Synthesis of Charge Transport Polymer 2>

A three-neck round-bottom flask was charged with the monomer A1 shown above (5.0 mmol), a monomer B2 shown below (2.0 mmol), the monomer D1 shown above (1.0 mmol), a monomer D2 shown below (3.0 mmol) and anisole (20 mL), and the prepared Pd catalyst solution (7.5 mL) was then added. Thereafter, synthesis of a charge transport polymer 2 was performed in the same manner as the synthesis of the charge transport polymer 1. The thus obtained charge transport polymer 2 had a number average molecular of 23,100 and a weight average molecular weight of 209,400. The charge transport polymer 2 had a structural unit (1a) (derived from the monomer A1), a structural unit (6b) (derived from the monomer B2), a structural unit (1d) having an oxetane group (derived from the monomer D1) and a structural unit (1d) having an alkyl group (derived from the monomer D2), and the proportions of those structural units were 45.5%, 18.2%, 9.1% and 27.3% respectively.

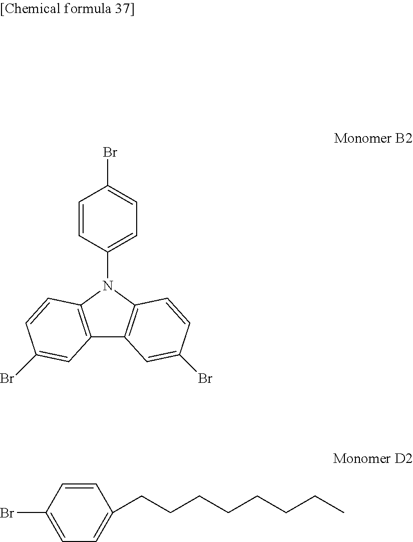

### <Synthesis of Charge Transport Polymer 3>

A three-neck round-bottom flask was charged with the monomer A1 shown above (5.0 mmol), the monomer B2 shown above (2.0 mmol), a monomer C1 shown below (3.0 mmol), the monomer D 1 shown above (1.0 mmol) and anisole (20 mL), and the prepared Pd catalyst solution (7.5 mL) was then added. Thereafter, synthesis of a charge transport polymer 3 was performed in the same manner as the synthesis of the charge transport polymer 1. The thus obtained charge transport polymer 3 had a number average molecular of 8,800 and a weight average molecular weight of 25,700. The charge transport polymer 3 had a structural unit (1a) (derived from the monomer A1), a structural unit (6b) (derived from the monomer B2), a structural unit (1c) (derived from the monomer C1) and a structural unit (1d) having an oxetane group (derived from the monomer D1), and the proportions of those structural units were 45.5%, 18.2%, 27.3% and 9.1% respectively.

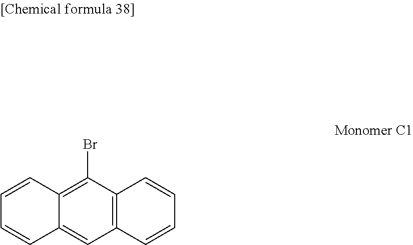

### <Synthesis of Charge Transport Polymer 4>

A three-neck round-bottom flask was charged with the monomer A1 shown above (5.0 mmol), the monomer B2 shown above (2.0 mmol), a monomer C2 shown below (3.0 mmol), the monomer D 1 shown above (1.0 mmol) and anisole (20 mL), and the prepared Pd catalyst solution (7.5 mL) was then added. Thereafter, synthesis of a charge transport polymer 4 was performed in the same manner as the synthesis of the charge transport polymer 1. The thus obtained charge transport polymer 4 had a number average molecular of 6,600 and a weight average molecular weight of 30,000. The charge transport polymer 4 had a structural unit (1a) (derived from the monomer A1), a structural unit (6b) (derived from the monomer B2), a structural unit (1c) (derived from the monomer C2) and a structural unit (1d) having an oxetane group (derived from the monomer D1), and the proportions of those structural units were 45.5%, 18.2%, 27.3% and 9.1% respectively.

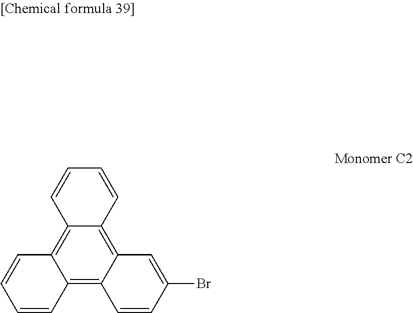

### <Synthesis of Charge Transport Polymer 5>

A three-neck round-bottom flask was charged with the monomer A1 shown above (5.0 mmol), the monomer B2 shown above (2.0 mmol), a monomer C3 shown below (3.0 mmol), the monomer D 1 shown above (1.0 mmol) and anisole (20 mL), and the prepared Pd catalyst solution (7.5 mL) was then added. Thereafter, synthesis of a charge transport polymer 5 was performed in the same manner as the synthesis of the charge transport polymer 1. The thus obtained charge transport polymer 5 had a number average molecular of 7,400 and a weight average molecular weight of 26,200. The charge transport polymer 5 had a structural unit (1a) (derived from the monomer A1), a structural unit (6b) (derived from the monomer B2), a structural unit (1c) (derived from the monomer C3) and a structural unit (1d) having an oxetane group (derived from the monomer D1), and the proportions of those structural units were 45.5%, 18.2%, 27.3% and 9.1% respectively.

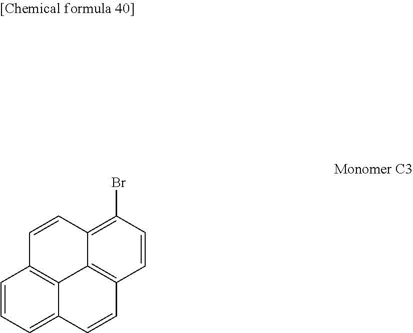

### <Synthesis of Charge Transport Polymer 6>

A three-neck round-bottom flask was charged with the monomer A1 shown above (5.0 mmol), the monomer B1 shown above (2.0 mmol), the monomer C1 shown above (3.0 mmol), the monomer D1 shown above (1.0 mmol) and anisole (20 mL), and the prepared Pd catalyst solution (7.5 mL) was then added. Thereafter, synthesis of a charge transport polymer 6 was performed in the same manner as the synthesis of the charge transport polymer 1. The thus obtained charge transport polymer 6 had a number average molecular of 17,400 and a weight average molecular weight of 103,100. The charge transport polymer 6 had a structural unit (1a) (derived from the monomer A1), a structural unit (2b) (derived from the monomer B1), a structural unit (1c) (derived from the monomer C1) and a structural unit (1d) having an oxetane group (derived from the monomer D1), and the proportions of those structural units were 45.5%, 18.2%, 27.3% and 9.1% respectively.

### <Synthesis of Charge Transport Polymer 7>

A three-neck round-bottom flask was charged with the monomer A1 shown above (5.0 mmol), the monomer B1 shown above (2.0 mmol), the monomer C2 shown above (3.0 mmol), the monomer D1 shown above (1.0 mmol) and anisole (20 mL), and the prepared Pd catalyst solution (7.5 mL) was then added. Thereafter, synthesis of a charge transport polymer 7 was performed in the same manner as the synthesis of the charge transport polymer 1. The thus obtained charge transport polymer 7 had a number average molecular of 28,500 and a weight average molecular weight of 209,100. The charge transport polymer 7 had a structural unit (1a) (derived from the monomer A1), a structural unit (2b) (derived from the monomer B1), a structural unit (1c) (derived from the monomer C2) and a structural unit (1d) having an oxetane group (derived from the monomer D1), and the proportions of those structural units were 45.5%, 18.2%, 27.3% and 9.1% respectively.

### <Synthesis of Charge Transport Polymer 8>

A three-neck round-bottom flask was charged with the monomer A1 shown above (5.0 mmol), the monomer B1 shown above (2.0 mmol), the monomer C3 shown above (3.0 mmol), the monomer D1 shown above (1.0 mmol) and anisole (20 mL), and the prepared Pd catalyst solution (7.5 mL) was then added. Thereafter, synthesis of a charge transport polymer 8 was performed in the same manner as the synthesis of the charge transport polymer 1. The thus obtained charge transport polymer 8 had a number average molecular of 20,700 and a weight average molecular weight of 142,000. The charge transport polymer 8 had a structural unit (1a) (derived from the monomer A1), a structural unit (2b) (derived from the monomer B1), a structural unit (1c) (derived from the monomer C3) and a structural unit (1d) having an oxetane group (derived from the monomer D1), and the proportions of those structural units were 45.5%, 18.2%, 27.3% and 9.1% respectively.

### <Synthesis of Charge Transport Polymer 9>

A three-neck round-bottom flask was charged with the monomer A1 shown above (5.0 mmol), the monomer B2 shown above (2.0 mmol), a monomer D3 shown below (3.0 mmol), the monomer D1 shown above (1.0 mmol) and anisole (20 mL), and the prepared Pd catalyst solution (7.5 mL) was then added. Thereafter, synthesis of a charge transport polymer 9 was performed in the same manner as the synthesis of the charge transport polymer 1. The thus obtained charge transport polymer 9 had a number average molecular of 30,900 and a weight average molecular weight of 123,000. The charge transport polymer 9 had a structural unit (1a) (derived from the monomer A1), a structural unit (6b) (derived from the monomer B2), a structural unit (1d) having a naphthalene ring (derived from the monomer D3) and a structural unit (1d) having an oxetane group (derived from the monomer D1), and the proportions of those structural units were 45.5%, 18.2%, 27.3% and 9.1% respectively.

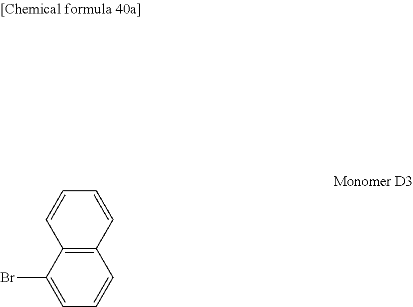

### <Synthesis of Charge Transport Polymer 10>

A three-neck round-bottom flask was charged with the monomer A2 shown below (5.0 mmol), the monomer B2 shown above (2.0 mmol), the monomer D2 shown above (3.0 mmol), the monomer D1 shown above (1.0 mmol) and anisole (20 mL), and the prepared Pd catalyst solution (7.5 mL) was then added. Thereafter, synthesis of a charge transport polymer 10 was performed in the same manner as the synthesis of the charge transport polymer 1. The thus obtained charge transport polymer 10 had a number average molecular of 17,500 and a weight average molecular weight of 54,800. The charge transport polymer 10 had a structural unit having an anthracene structure (derived from the monomer A2), a structural unit (6b) (derived from the monomer B2), a structural unit (1d) having an alkyl group (derived from the monomer D2) and a structural unit (1d) having an oxetane group (derived from the monomer D1), and the proportions of those structural units were 45.5%, 18.2%, 27.3% and 9.1% respectively.

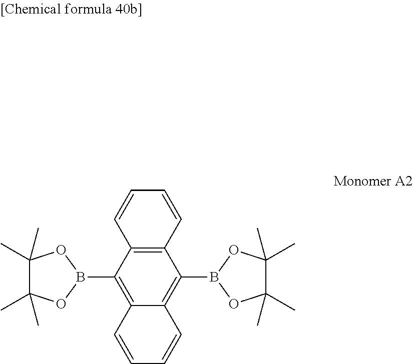

### <Synthesis of Charge Transport Polymer 11>

A three-neck round-bottom flask was charged with the monomer A1 shown above (5.0 mmol), the monomer B2 shown above (2.0 mmol), a monomer C4 shown below (3.0 mmol), the monomer D1 shown above (1.0 mmol) and anisole (20 mL), and the prepared Pd catalyst solution (7.5 mL) was then added. Thereafter, synthesis of a charge transport polymer 11 was performed in the same manner as the synthesis of the charge transport polymer 1. The thus obtained charge transport polymer 11 had a number average molecular of 24,800 and a weight average molecular weight of 62,000. The charge transport polymer 11 had a structural unit (1a) (derived from the monomer A1), a structural unit (6b) (derived from the monomer B2), a structural unit (1c) (derived from the monomer C4) and a structural unit (1d) having an oxetane group (derived from the monomer D1), and the proportions of those structural units were 45.5%, 18.2%, 27.3% and 9.1% respectively.

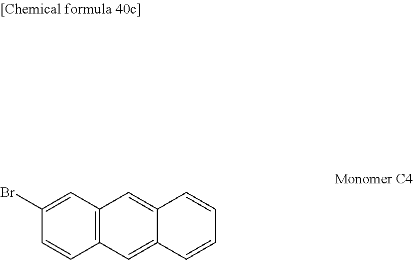

### <Synthesis of Charge Transport Polymer 12>

A three-neck round-bottom flask was charged with the monomer A1 shown above (5.0 mmol), the monomer B2 shown above (2.0 mmol), a monomer C5 shown below (3.0 mmol), the monomer D1 shown above (1.0 mmol) and anisole (20 mL), and the prepared Pd catalyst solution (7.5 mL) was then added. Thereafter, synthesis of a charge transport polymer 12 was performed in the same manner as the synthesis of the charge transport polymer 1. The thus obtained charge transport polymer 12 had a number average molecular of 29,000 and a weight average molecular weight of 58,800. The charge transport polymer 12 had a structural unit (1a) (derived from the monomer A1), a structural unit (6b) (derived from the monomer B2), a structural unit (1c) (derived from the monomer C5) and a structural unit (1d) having an oxetane group (derived from the monomer D1), and the proportions of those structural units were 45.5%, 18.2%, 27.3% and 9.1% respectively.

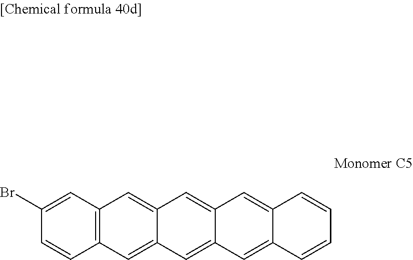

### <Production of Organic EL Elements>

### Example 1

Under a nitrogen atmosphere, an ink composition was prepared by mixing the charge transport polymer 1 (10.0 mg), an electron-accepting compound 1 shown below (0.5 mg) and toluene (2.3 mL). This ink composition was spin-coated at a rotational rate of 3,000 min⁻¹ onto a glass substrate on which ITO had been patterned with a width of 1.6 mm, and was then cured by heating at 220° C. for 10 minutes on a hotplate, thus forming a hole injection layer (25 nm).

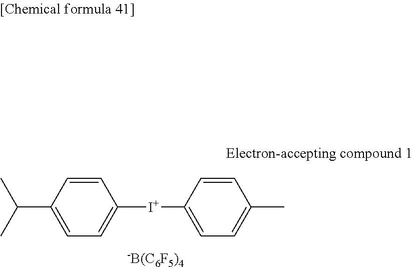 [SMILES: "-B(C6F5)4" ; Cc1ccc([I+]c2ccc(C(C)C)cc2)cc1]

Next, an ink composition was prepared by mixing the charge transport polymer 3 (10.0 mg) and toluene (1.15 mL). This ink composition was spin-coated at a rotational rate of 3,000 min⁻¹ onto the hole injection layer formed above, and was then cured by heating at 200° C. for 10 minutes on a hotplate, thus forming a hole transport layer (40 nm). The hole transport layer was able to be formed without dissolving the hole injection layer.

The thus obtained substrate was transferred into a vacuum deposition apparatus, layers of CBP:Ir(ppy)₃ (94:6, 30 nm), BAlq (10 nm), TPBi (30 nm), LiF (0.8 nm) and Al (100 nm) were deposited in that order using deposition methods on top of the hole transport layer, and an encapsulation treatment was then performed to complete production of an organic EL element.

### Example 2

With the exception of replacing the charge transport polymer 3 with the charge transport polymer 4 in the formation step for the hole transport layer, an organic EL element was produced in the same manner as Example 1.

### Example 3

With the exception of replacing the charge transport polymer 3 with the charge transport polymer 5 in the formation step for the hole transport layer, an organic EL element was produced in the same manner as Example 1.

### Example 4

With the exception of replacing the charge transport polymer 3 with the charge transport polymer 11 in the formation step for the hole transport layer, an organic EL element was produced in the same manner as Example 1.

### Example 5

With the exception of replacing the charge transport polymer 3 with the charge transport polymer 12 in the formation step for the hole transport layer, an organic EL element was produced in the same manner as Example 1.

### Comparative Example 1

With the exception of replacing the charge transport polymer 3 with the charge transport polymer 2 in the formation step for the hole transport layer, an organic EL element was produced in the same manner as Example 1.

### Comparative Example 2

With the exception of replacing the charge transport polymer 3 with the charge transport polymer 9 in the formation step for the hole transport layer, an organic EL element was produced in the same manner as Example 1.

### Comparative Example 3

With the exception of replacing the charge transport polymer 3 with the charge transport polymer 10 in the formation step for the hole transport layer, an organic EL element was produced in the same manner as Example 1.

The layer configurations of the organic EL elements produced in Examples 1 to 5 and Comparative Examples 1 to 3 are summarized in Table 1.

TABLE 1

| | | Hole Transport |
|---|---|---|
| | Hole Injection Layer | Layer |
| Example 1 | Charge transport polymer 1 | Charge transport |
| | Electron-accepting compound 1 | polymer 3 |
| Example 2 | Charge transport polymer 1 | Charge transport |
| | Electron-accepting compound 1 | polymer 4 |
| Example 3 | Charge transport polymer 1 | Charge transport |
| | Electron-accepting compound 1 | polymer 5 |
| Example 4 | Charge transport polymer 1 | Charge transport |
| | Electron-accepting compound 1 | polymer 11 |
| Example 5 | Charge transport polymer 1 | Charge transport |
| | Electron-accepting compound 1 | polymer 12 |
| Comparative | Charge transport polymer 1 | Charge transport |
| Example 1 | Electron-accepting compound 1 | polymer 2 |
| Comparative | Charge transport polymer 1 | Charge transport |
| Example 2 | Electron-accepting compound 1 | polymer 9 |
| Comparative | Charge transport polymer 1 | Charge transport |
| Example 3 | Electron-accepting compound 1 | polymer 10 |

When a voltage was applied to each of the organic EL elements obtained in Examples 1 to 5 and Comparative Examples 1 to 3, a green light emission was confirmed in each case. For each element, the emission efficiency at an emission luminance of 1,000 cd/m², and the emission lifespan (luminance half-life) when the initial luminance was 5,000 cd/m² were measured. The measurement results are shown in Table 2.

TABLE 2

| | Emission efficiency | Emission lifespan |
|---|---|---|
| | (cd/A) | (h) |
| Example 1 | 36.2 | 105.7 |
| Example 2 | 37.8 | 120.1 |
| Example 3 | 35.4 | 112.9 |
| Example 4 | 35.0 | 110.9 |
| Example 5 | 35.2 | 119.2 |
| Comparative Example 1 | 33.4 | 84.8 |
| Comparative Example 2 | 32.9 | 89.2 |
| Comparative Example 3 | 30.2 | 75.3 |

As shown in Table 2, by using the organic electronic material that represents an embodiment of the present invention as a hole transport layer, elements having high emission efficiency and a long lifespan with excellent drive stability were able to be obtained.

### Example 6

Under a nitrogen atmosphere, an ink composition was prepared by mixing the charge transport polymer 6 (10.0 mg), the electron-accepting compound 1 shown above (0.5 mg) and toluene (2.3 mL). This ink composition was spin-coated at a rotational rate of 3,000 min⁻¹ onto a glass substrate on which ITO had been patterned with a width of 1.6 mm, and was then cured by heating at 220° C. for 10 minutes on a hotplate, thus forming a hole injection layer (25 nm).

Next, an ink composition was prepared by mixing the charge transport polymer 2 (10.0 mg) and toluene (1.15 mL). This ink composition was spin-coated at a rotational rate of 3,000 min⁻¹ onto the hole injection layer formed above, and was then cured by heating at 200° C. for 10 minutes on a hotplate, thus forming a hole transport layer (40 nm). The hole transport layer was able to be formed without dissolving the hole injection layer.

The thus obtained substrate was transferred into a vacuum deposition apparatus, layers of CBP:Ir(ppy)₃ (94:6, 30 nm), BAlq (10 nm), TPBi (30 nm), LiF (0.8 nm) and Al (100 nm) were deposited in that order using deposition methods on top of the hole transport layer, and an encapsulation treatment was then performed to complete production of an organic EL element.

### Example 7

With the exception of replacing the charge transport polymer 6 with the charge transport polymer 7 in the formation step for the hole injection layer, an organic EL element was produced in the same manner as Example 6.

### Example 8

With the exception of replacing the charge transport polymer 6 with the charge transport polymer 8 in the formation step for the hole injection layer, an organic EL element was produced in the same manner as Example 6.

The layer configurations of the organic EL elements produced in Examples 6 to 8 and Comparative Example 1 are summarized in Table 3.

TABLE 3

| | | Hole Transport |
|---|---|---|
| | Hole Injection Layer | Layer |
| Example 6 | Charge transport polymer 6 | Charge transport |
| | Electron-accepting compound 1 | polymer 2 |
| Example 7 | Charge transport polymer 7 | Charge transport |
| | Electron-accepting compound 1 | polymer 2 |
| Example 8 | Charge transport polymer 8 | Charge transport |
| | Electron-accepting compound 1 | polymer 2 |
| Comparative | Charge transport polymer 1 | Charge transport |
| Example 1 | Electron-accepting compound 1 | polymer 2 |

When a voltage was applied to each of the organic EL elements obtained in Examples 6 to 8 and Comparative Example 1, a green light emission was confirmed in each case. For each element, the emission efficiency at an emission luminance of 1,000 cd/m², and the emission lifespan (luminance half-life) when the initial luminance was 5,000 cd/m² were measured. The measurement results are shown in Table 4.

TABLE 4

| | Emission efficiency | Emission lifespan |
|---|---|---|
| | (cd/A) | (h) |
| Example 6 | 34.8 | 103.1 |
| Example 7 | 35.2 | 106.2 |
| Example 8 | 34.3 | 99.5 |
| Comparative Example 1 | 33.4 | 84.8 |

As shown in Table 4, by using the organic electronic material that represents an embodiment of the present invention as a hole injection layer, elements having high emission efficiency and a long lifespan with excellent drive stability were able to be obtained.

### <Production of White Organic EL Element (Illumination Device)>

### Example 9

Under a nitrogen atmosphere, an ink composition was prepared by mixing the charge transport polymer 1 (10.0 mg), the electron-accepting compound 1 shown above (0.5 mg) and toluene (2.3 mL). This ink composition was spin-coated at a rotational rate of 3,000 min⁻¹ onto a glass substrate on which ITO had been patterned with a width of 1.6 mm, and was then cured by heating at 220° C. for 10 minutes on a hotplate, thus forming a hole injection layer (25 nm).

Next, an ink composition was prepared by mixing the charge transport polymer 1 (10.0 mg), the charge transport polymer 4 (10.0 mg) and toluene (1.15 mL). This ink composition was spin-coated at a rotational rate of 3,000 min⁻¹ onto the hole injection layer, and was then cured by heating at 200° C. for 10 minutes on a hotplate, thus forming a hole transport layer (40 nm). The hole transport layer was able to be formed without dissolving the hole injection layer.

Subsequently, an ink composition was prepared in a nitrogen atmosphere by mixing CDBP (15.0 mg), FIr(pic) (0.9 mg), Ir(ppy)₃ (0.9 mg), (btp)₂Ir(acac) (1.2 mg) and dichlorobenzene (0.5 mL). This ink composition was spin-coated at a rotational rate of 3,000 min⁻¹, and then cured by heating at 80° C. for 5 minutes on a hotplate, thus forming a light-emitting layer (40 nm). The light-emitting layer was able to be formed without dissolving the hole transport layer.

The glass substrate was then transferred into a vacuum deposition apparatus, layers of BAlq (10 nm), TPBi (30 nm), LiF (0.5 nm) and Al (100 nm) were deposited in that order using deposition methods on top of the light-emitting layer. An encapsulation treatment was then performed to complete production of a white organic EL element. The white organic EL element was able to be used as an illumination device.

### Comparative Example 4

With the exception of replacing the charge transport polymer 4 with the charge transport polymer 2, a white organic EL element was produced in the same manner as Example 9. The light-emitting layer was able to be formed without dissolving the hole transport layer. The white organic EL element was able to be used as an illumination device.

A voltage was applied to each of the white organic EL elements obtained in Example 9 and Comparative Example 4, and the emission lifespan (luminance half-life) when the initial luminance was 1,000 cd/m² was measured. When the emission lifespan in Example 9 was deemed to be 1, the result in Comparative Example 4 was 0.72. Further, when the voltage at a luminance of 1,000 cd/m² in Example 9 was deemed to be 1, the result in Comparative Example 4 was 1.12.

The white organic EL element of Example 9 displayed an excellent emission lifespan and drive voltage.

The effects of embodiments of the present invention have been described above using a series of examples. In addition to the charge transport polymers used in the above examples, other charge transport polymers described above can also be used to obtain organic EL elements having a long lifespan, and similar superior effects can be achieved.

### REFERENCE SIGNS LIST

1: Light-emitting layer
2: Anode
3: Hole injection layer
4: Cathode
5: Electron injection layer
6: Hole transport layer
7: Electron transport layer
8: Substrate

1. An organic electronic material comprising a charge transport polymer or oligomer having, at least at one terminal, a condensed polycyclic aromatic hydrocarbon moiety having three or more benzene rings.

2. The organic electronic material according to claim 1, wherein the charge transport polymer or oligomer has three or more terminals.

3. The organic electronic material according to claim 1, wherein the charge transport polymer or oligomer has the condensed polycyclic aromatic hydrocarbon moiety at 25% or more of all terminals.

4. The organic electronic material according to claim 1, wherein the condensed polycyclic aromatic hydrocarbon moiety comprises at least one type of moiety selected from the group consisting of an anthracene moiety, tetracene moiety, pentacene moiety, phenanthrene moiety, chrysene moiety, triphenylene moiety, tetraphene moiety, pyrene moiety, picene moiety, pentaphene moiety, perylene moiety, pentahelicene moiety, hexahelicene moiety, heptahelicene moiety and coronene moiety.

5. The organic electronic material according to claim 1, wherein the condensed polycyclic aromatic hydrocarbon moiety comprises a condensed polycyclic aromatic hydrocarbon moiety having 3 to 8 benzene rings.

6. The organic electronic material according to claim 1, wherein the charge transport polymer or oligomer also has a polymerizable substituent.

7. An ink composition comprising the organic electronic material according to claim 1, and a solvent.

8. An organic layer formed using the organic electronic material according to claim 1.

9. An organic electronic element comprising at least one organic layer according to claim 8.

10. An organic electroluminescent element comprising at least one organic layer according to claim 8.

11. The organic electroluminescent element according to claim 10, further comprising a flexible substrate.

12. The organic electroluminescent element according to claim 10, also further comprising a resin film substrate.

13. A display element comprising the organic electroluminescent element according to claim 10.

14. An illumination device comprising the organic electroluminescent element according to claim 10.

15. A display device comprising the illumination device according to claim 14, and a liquid crystal element as a display unit.

16. An organic layer formed using the ink composition according to claim 7.
